(19) United States
(12) Patent Application Publication
(10) Pub. No.: US 2026/0265909 A1
(43) Pub. Date: Sep. 10, 2026

(54) FLASH-ENHANCED ATOMIC LAYER DEPOSITION AND CHEMICAL VAPOR DEPOSITION OF METALS

(71) Applicant: Lam Research Corporation, Fremont, CA (US)

(72) Inventors: David Joseph Mandia, Lake Oswego, OR (US); Clint Edward Thomas, Timnath, CO (US); Panya Wongsenakhum, Fremont, CA (US); Sivananda Krishnan Kanakasabapathy, Pleasanton, CA (US); Chiukin Steven Lai, Sunnyvale, CA (US); Matthew Bertram Edward Griffiths, Campbell, CA (US)

(21) Appl. No.: 19/473,331

(22) PCT Filed: Apr. 2, 2024
(86) PCT No.: PCT/US2024/022681

§ 371 Date: Oct. 7, 2025

Related U.S. Application Data
(60) Provisional application No. 63/496,308, filed on Apr. 14, 2023.

(51) Int. Cl. C23C 16/455; C23C 16/48; C23C 16/52

(52) U.S. Cl. CPC C23C 16/45536; C23C 16/45544; C23C 16/45553; C23C 16/45565; C23C 16/482; C23C 16/52

(57) ABSTRACT

Low temperature metal-containing film deposition methods include introducing reagents into a process chamber housing a semiconductor substrate and applying pulses of light from a light source to the semiconductor substrate, creating a rapid and transitory increase in the temperature of the top surface and/or nucleation layer of the semiconductor substrate. The substrate may be irradiated during metal precursor delivery, during reducing agent delivery or during purges. The flash enhanced deposition of molybdenum, tungsten or ruthenium optionally may include application of light to a dielectric material as a pre-treatment and/or a post-treatment.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety.

### BACKGROUND

In semiconductor device fabrication, deposition and etching techniques are used for forming patterns of materials, such as for forming metal lines embedded in dielectric layers. Some patterning schemes require conformal deposition of materials, where the deposited layer should follow the contour of protrusions and/or recessed features on the surface of the substrate. Atomic layer deposition (ALD) is often a preferred method of forming conformal films on a substrate because ALD relies on adsorption of one or more reactants to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, this method can provide thin conformal layers having excellent step coverage.

Chemical vapor deposition (CVD) is another deposition method widely used in semiconductor processing. In CVD, the reaction occurs in the volume of the process chamber and is not limited by the amount of reactants adsorbed to the substrate. As a result, CVD-deposited films are often less conformal than ALD-deposited films. CVD is typically used in applications where step coverage is less important.

While ALD and CVD are most commonly used for deposition of silicon-containing films, such as silicon oxide, silicon nitride, and silicon carbide, these methods are also suitable for deposition of some metals. Deposition of metal-containing films at lower temperatures (below 400° C.) would be advantageous for certain applications. At such reduced temperatures, the likelihood of impurities is increased. Therefore, ALD or CVD processes which can be performed at a lower temperature and which can minimize impurities are desirable.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Low temperature metal-containing film deposition methods and apparatus for performing the same includes introducing reagents into a process chamber housing a semiconductor substrate and applying pulses of light from a light source to the semiconductor substrate, creating a rapid and transitory increase in the temperature of the top surface and/or nucleation layer of the semiconductor substrate. Contacting the semiconductor substrate with pulses of light from a light source such as a flash lamp induces a temperature of the topmost surface and/or nucleation layer higher than a temperature of the bulk substrate. The substrate may be irradiated with pulses of light during metal precursor delivery, during reducing agent delivery or during purges. The flash enhanced deposition of molybdenum, tungsten or ruthenium optionally may include application of light to the substrate as a pre-treatment and/or a post-treatment.

Accordingly, in a first aspect, the present disclosure encompasses a method for deposition of metal-containing films. In some embodiments, the method includes providing a semiconductor substrate in a processing chamber, the semiconductor substrate having a top surface and a bulk, the top surface positioned above the bulk; introducing a metal precursor into the processing chamber; irradiating the top surface with pulses of light from a light source; introducing a reducing agent into the processing chamber; and depositing a metal-containing film on the semiconductor substrate, wherein the processing chamber is maintained at a temperature of about 450° C. or less.

In some embodiments, light source emits pulses of light of a wavelength of from about 400 to about 1100 nanometers for a duration of 0.2 microseconds to 10 milliseconds.

In some embodiments, irradiating the semiconductor substrate with pulses of light induces a transitory elevated temperature on the top surface.

In some embodiments, irradiating the semiconductor substrate with pulses of light induces a temperature of the top surface higher than a temperature of the bulk.

In some embodiments, the temperature of the top surface is from about 500° C. to about 800° C., and the temperature of the bulk is less than 450° C.

In some embodiments, the transitory elevated temperature on the top surface facilitates nucleation of the metal-containing film at the top surface of the semiconductor substrate.

In some embodiments, the metal is molybdenum, tungsten or ruthenium and the semiconductor substrate is silicon dioxide.

In some embodiments, the metal precursor is a molybdenum precursor.

In some embodiments, the molybdenum precursor has a structure of Formula (I), Formula (II) or Formula (III): MoLₙ (I), Mo₂Lₙ (II), or LₙMo(L′)ₘMoLₙ (III), wherein each L is independently a monodentate ligand, ambidentate ligand, bidentate ligand or tridentate ligand, L′ is a linking moiety, n is 2, 3, 4, 5 or 6; and m is 1, 2 or 3.

In some embodiments, each L is independently a monodentate ligand.

In some embodiments, the monodentate ligand is hydrogen, halo, hydroxy, alkyl silyl, silylalkyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, CO, —O, ═S, ≡N, —NO, aralkenyl, aralkyl, sulfonyl, sulfonamido, sulfonimido, carbamate, aryloxyalkyl, carboxyl, carboxy, —C(O)NH(benzyl), amido, azido, isocyanato, thiocyanato, isothiocyanato, cyano, isocyanoalkyl, isocyanohaloalkyl, isocyanoaryl, isocyanohaloaryl, or cyclyl.

In some embodiments, the molybdenum is a molybdenum halide or a molybdenum oxyhalide.

In some embodiments, the molybdenum oxyhalide is Mo_{q}OₙYₘ, wherein Y is a halogen; n is 1 or 2; q is 1, 2 or 4; and m is 1, 2 or 11.

In some embodiments, the molybdenum oxyhalide is MoOF₄, Mo₄O₁₁I, MoO₂I, MoOBr₄, MoO₂Br₂, MoO₂Cl₂, MoOCH₄, Mo₂Cl₁₀, or a combination thereof.

In some embodiments, the molybdenum halide is MoCl₅. Mo₂Cl₁₀, MoF₆, or a combination thereof.

In some embodiments, the molybdenum precursor is Mo(CO)₆ or C₁₆H₂₀Mo.

In some embodiments, the molybdenum precursor is a low valent molybdenum precursor.

In some embodiments, the low valent molybdenum precursor has an oxidation state of zero, one, two, or three.

In some embodiments, the molybdenum precursor is bis(ethylbenzene)molybdenum.

In some embodiments, the light source is a xenon flash lamp.

In some embodiments, the xenon flash lamp is configured above the semiconductor substrate.

In some embodiments, pulses of light are emitted parallel to the semiconductor substrate or perpendicular to the semiconductor substrate.

In some embodiments, pulses of light have an energy density of from about 1 J/cm² to about 10 J/cm².

In some embodiments, irradiating the semiconductor substrate with pulses of light occurs while introducing the metal precursor into the process chamber.

In some embodiments, introducing the reducing agent into the process chamber occurs after introducing the metal precursor into the process chamber.

In some embodiments, the method includes purging the processing chamber with an inert gas.

In some embodiments, purging the process chamber with an inert gas occurs before and after introducing the reducing agent into the process chamber.

In some embodiments, introducing the reducing agent into the process chamber occurs continuously.

In some embodiments, irradiating the semiconductor substrate with pulses of light occurs after introducing a metal precursor into the processing chamber.

In some embodiments, irradiating the semiconductor substrate with pulses of light occurs before, after, or before and after introducing the reducing agent into the process chamber.

In some embodiments, purging the process chamber comprises purging with an inert gas before and after introducing the reducing agent into the process chamber.

In some embodiments, irradiating the semiconductor substrate with pulses of light occurs during the purging of the process chamber.

In some embodiments, the method also includes annealing the semiconductor substrate by irradiating the semiconductor substrate with pulses of light subsequent to purging the process chamber after introducing the reducing agent into the process chamber.

In some embodiments, the method also includes pre-treating the semiconductor substrate by irradiating the semiconductor substrate with pulses of light.

In some embodiments, the low temperature deposition is atomic layer deposition, no-purge atomic layer deposition or pulsed chemical vapor deposition.

In some embodiments, the semiconductor substrate has recessed features.

In some embodiments, deposition occurs without increasing thermal stress on the semiconductor substrate.

In some embodiments, the semiconductor substrate also includes a nucleation layer, the nucleation layer positioned above the bulk and below the top surface.

In some embodiments, irradiating the semiconductor substrate with pulses of light induces a temperature of the top surface and the nucleation layer higher than a temperature of the bulk.

In a second aspect, the present disclosure encompasses an apparatus for processing substrates. In some embodiments, the apparatus includes one or more process chambers configured to receive a semiconductor substrate; one or more light sources configured above the semiconductor substrate; one or more gas inlets into the process chambers and associated flow-control hardware; and a controller having at least one processor and a memory, wherein the at least one processor and the memory are communicatively connected with one another, the at least one processor is at least operatively connected with the associated flow-control hardware, and the memory stores computer-executable instructions for controlling the at least one processor to at least control the associated flow-control hardware to: cause emission of pulses of light from the one or more light sources to induce a transitory elevated temperature of a top surface of a semiconductor substrate and cause deposition of a metal-containing film on the semiconductor substrate.

In some embodiments, pulses of light are emitted from the one or more light sources at a wavelength from about 400 to about 1100 nanometers for a duration of 0.2 microseconds to 10 milliseconds.

In some embodiments, the one or more light sources emit light parallel to the semiconductor substrate or perpendicular to the semiconductor substrate.

In some embodiments, the apparatus also includes a showerhead within the one or more process chambers.

In some embodiments, the showerhead is configured to house the one or more light sources.

In some embodiments, the one or more light sources is configured above the showerhead, and the showerhead is transparent to light.

These and other aspects are described further below with reference to the drawings.

### BRIEF DESCRIPTION OF THE DRAWINGS

FIG. 1 is a process flow diagram for a method of deposition of a metal with exposure to flashes of light during various operations in accordance with certain disclosed embodiments.

FIGS. 2A-2C illustrate a deposition method in which flashes of light irradiate the substrate during the delivery of the precursor in accordance with certain disclosed embodiments.

FIGS. 3A-3B illustrate a deposition method in which flashes of light irradiate the substrate during purge steps in accordance with certain disclosed embodiments.

FIG. 4 illustrates a deposition method in which the flashes of light irradiate the substrate during purge steps and as a post-treatment in accordance with certain disclosed embodiments.

FIG. 5 is a schematic presentation of a process chamber configured to enable irradiation of a substrate from a side orientation in accordance with certain disclosed embodiments.

FIG. 6 is a schematic presentation of a process chamber configured to enable irradiation of a substrate from an upper orientation in accordance with certain disclosed embodiments.

FIG. 7 is a schematic presentation of an apparatus that is suitable for depositing metals in accordance with certain disclosed embodiments.

FIG. 8 shows a schematic view of a multi-station processing system in accordance with certain disclosed embodiments.

FIG. 9 shows a schematic view of a multi-station processing system in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Introduction and Context

Heating of substrates may be performed with a traditional lamp such as an infrared lamp. The lamp may heat a portion of a substrate, for example, at 40-250° C./second. Time for the lamp to heat the substrate surface and then for the substrate surface to subsequently cool down can take several minutes. The amount of time needed to heat up and cool down the substrate can be based on the heating and cooling rates of a substrate support, such as an electrostatic chuck. Time for the substrate and the substrate support to heat up and cool down can take on the order of tens of minutes.

Due to the lengthy period to heat the substrate, the entire substrate including a base or bulk portion of the substrate is typically heated. As a result, traditional heating by turning on a heating lamp for an extended period of time has thermal budget issues due to the heating of a bulk portion of a substrate and not heating only an upper portion and/or a surface of the substrate. The thermal budget refers to an amount of time that a substrate is able to be exposed to particular temperatures without degrading materials and/or make-up of the substrate; negatively affecting performance and/or operation of die components on the substrate; and/or causing inter-diffusion issues, where molecules and/or atoms of one species are diffused into another species layer. In some embodiments, thermal stress causes degradation of materials and/or make-up of the substrate. The higher the temperature and the longer the exposure, the more likely there will be more thermal budget issues and the more prevalent those thermal budget issues will be.

These thermal budget issues limit the processes which may be performed on a substrate, especially within a single process chamber. In order to avoid having to wait for a substrate and support to cool down sufficiently to perform other operations, a substrate may have to be transferred to a different process chamber and/or tool.

In place of a traditional lamp, or moving the wafer to a different processing chamber, utilization of flash lamps allows the upper portion and/or surface semiconductor wafers to be heated in an extremely short time. Flash lamps may provide heat treatment using xenon flash lamps to irradiate the surface of a semiconductor wafer with flashes of light so that the temperature of only the surface of the semiconductor wafer is raised in an extremely short time (several milliseconds or less).

The radiation spectral distribution of xenon flash lamps ranges from ultraviolet to near-infrared regions, with the xenon flash lamps having shorter wavelengths than conventional halogen lamps, and approximately coincides with the fundamental absorption band of silicon semiconductor wafers. Thus, in the case where flashes of light are applied from xenon lamps to a semiconductor wafer, less light will be transmitted through the semiconductor layer, making it possible to quickly raise the temperature of the semiconductor wafer. It has also been found that the temperature of only the vicinity of the surface of the semiconductor wafer will selectively be raised with extremely short-time application of flashes of light for several milliseconds or less.

When a substrate is exposed to a flash from a flash lamp, only the device side surface of the substrate is heated. Due to the rapid heating rate of the device side during the flash (on the order of 10⁵° C./second), the bulk of the of the wafer remains at a lower temperature (such as the temperature from the heat source below the wafer) and acts as a heat sink to cool the device side surface following the flash. Moreover, although a flash lamp may require more time to cool down than it takes to heat up, both heat up and cool down operations are much faster with a flash lamp than for a conventional thermal heat source such as a furnace. Flash lamps have been incorporated into semiconductor manufacturing operations such as annealing and etching.

Pulsed thermal etching methods and systems are described for example in U.S. Pat. No. 10,224,212, issued Mar. 5, 2019 and entitled “ISOTROPIC ETCHING OF FILM WITH ATOMIC LAYER CONTROL”; U.S. Pat. Publication No. 2022/0005740, published Jan. 6, 2022 and entitled “ATOMIC LAYER ETCH SYSTEMS FOR SELECTIVELY ETCHING WITH HALOGEN-BASED COMPOUNDS”; and U.S. Pat. Publication No. 2022/0084838, published Mar. 17, 2022 and entitled “METAL ATOMIC LAYER ETCH AND DEPOSITION APPARATUSES AND PROCESSES WITH METAL-FREE LIGANDS”, the disclosures of which at least relating to the systems, apparatuses and techniques useful for semiconductor processing composition are incorporated by reference herein.

### The Methods

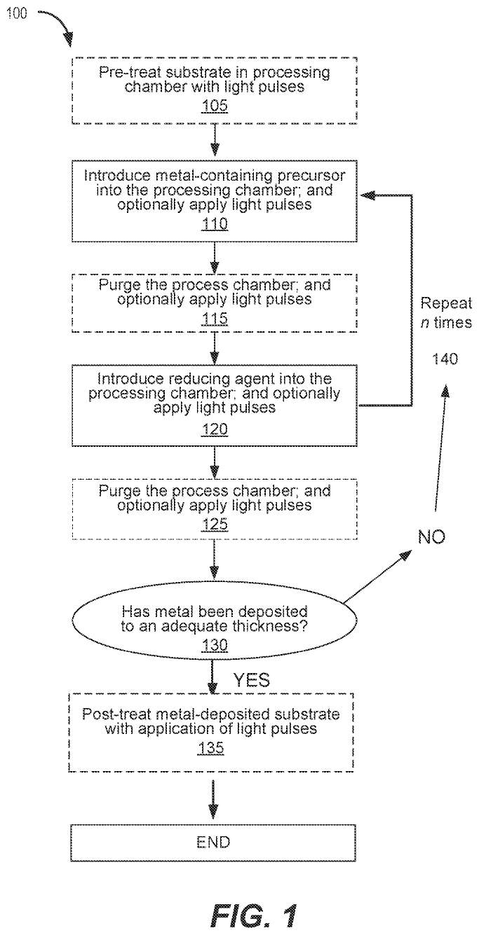

FIG. 1 is a flow chart illustrating a method 100 for deposition of a metal, such as a molybdenum, tungsten or ruthenium metal in accordance with certain disclosed embodiments. While provided method can be used on a variety of substrates, in some embodiments the method is used on substrates having recessed features that have different exposed materials at sidewalls and at the bottom. For example, in some embodiments the substrate has a recessed feature with an exposed metal on the bottom and with exposed dielectric on the sidewalls.

Molybdenum-containing films can be deposited for a variety of applications in semiconductor processing. In some embodiments molybdenum-containing films (e.g., molybdenum metal) is deposited as a conformal layer to a thickness of between about 0.1-10 nm on a substrate containing one or more recessed or protruding features. In some embodiments recessed features are filled with molybdenum-containing material (e.g., molybdenum metal). In general, the substrate may include a variety of materials including dielectrics, metals, metal nitrides, etc.

A conformal layer of molybdenum-containing material is deposited on the substrate using the methods and precursors described herein.

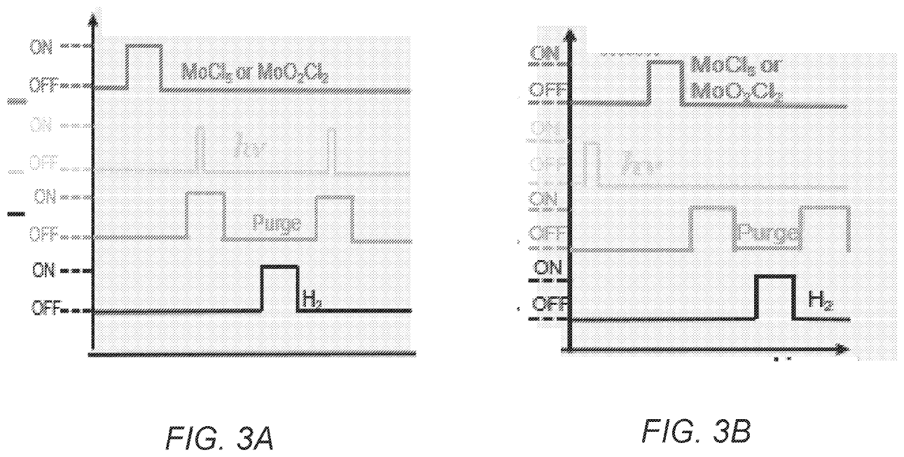

Operation 105 is an optional pre-treatment, in which a substrate housed in a processing chamber is irradiated with flashes of light, as described in detail below and with reference to FIG. 3B.

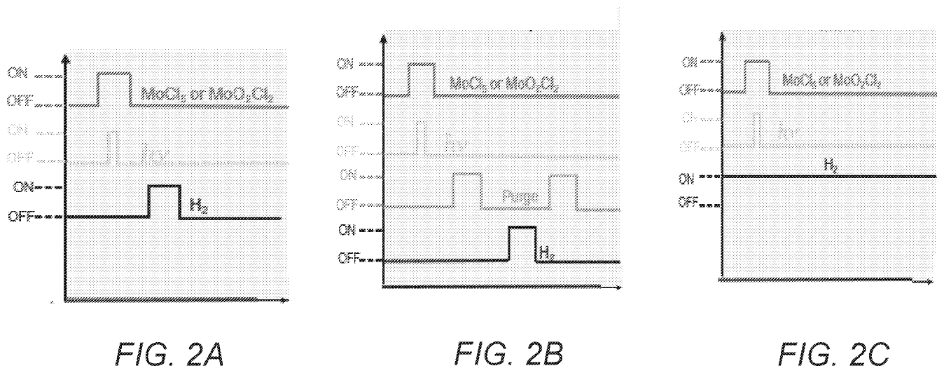

Returning to FIG. 1, operation 110 is an introduction of a metal-containing precursor into the processing chamber. The metal-containing precursor may be introduced for a duration of from 0.5 to 60 seconds in some embodiments. Optionally, the substrate may be irradiated with flashes of light during precursor introduction as described in detail below and with reference to FIGS. 2A-2C.

Returning to FIG. 1, operation 115 is an optional purge of the processing chamber. During the optional purge, the substrate may be irradiated with flashes of light. These operations and options are described in detail below and with reference to FIGS. 2B, 3A, 3B and 4.

Returning to FIG. 1, operation 120 is an introduction of a reducing agent into the process chamber. Optionally, the substrate may be irradiated with flashes of light during reducing agent introduction as described in detail below and with reference to FIG. 2C.

Returning to FIG. 1, operation 125 is an optional purge of the processing chamber. During the optional purge, the substrate may be irradiated with flashes of light. These operations and options as described in detail below and with reference to FIGS. 2B, 3A, 3B and 4.

Returning to FIG. 1, as shown in operation 130, if the film deposited is of adequate thickness, the method is completed and ends. As used herein, “metal-containing film” refers to a film only including metal or a film which contains a metal and additional components. Metal-containing films can be deposited for a variety of semiconductor applications. Therefore, the desired thickness will depend upon the particular application. In some embodiments metal-containing films may be deposited as a conformal layer to a thickness of between about 0.1-10 nm on a substrate.

If a thicker film is desired, process flow path 140 indicating that after operation 120, operation 110 can commence again, repeating n times. In process flow path 140, n is the number of cycles which may be from 1 to 50 or from 20 to 40. The cycle of operations 110, 120 and 130 can be repeated as many times as necessary. As used herein, the term “cycle” refers to a particular set of sequential operations.

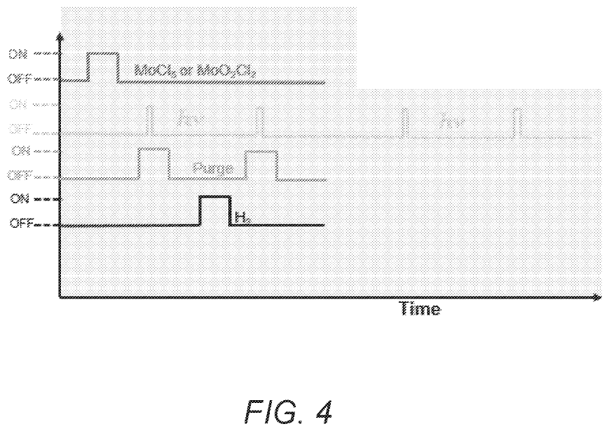

Subsequent to a determination in operation 130 that the metal-containing film deposited is of adequate thickness, optionally post-treatment operation 135 may be performed in which pulses of light are applied to the metal deposited substrate, as described in detail below and with reference to FIG. 4.

The recessed feature is filled with the molybdenum-containing material (e.g., with molybdenum metal). The molybdenum-containing film is deposited into the recessed feature, in some embodiments, using multiple depositions of conformal film for example by using a sequence of ALD cycles. In other embodiments the recessed feature may be filled using bottom-up film growth.

The molybdenum-containing films, and, particularly, high purity molybdenum metal, provided herein can be used in interconnect metallization (e.g., for filling recessed features to form contacts), in logic gate applications in FinFETs, as adhesion layers or diffusion barriers, and in 3D NAND fabrication. Examples of applications include logic and memory contact fill, DRAM buried wordline fill, vertically integrated memory gate, and wordline fill, and 3-D integration using through-silicon vias (TSV). The resistivity of molybdenum scales better than that of tungsten, and in some embodiments, molybdenum is particularly advantageous metal for filling narrow recessed features, e.g., features with widths of less than about 20 nm.

In one application, molybdenum metal is used for manufacturing barrierless contacts. In this application, molybdenum metal is deposited directly into the recessed features (contact holes) having widths of about 5-100 nm, e.g., about 5-20 nm, where the recessed features are formed in the dielectric layer, and include exposed dielectric, such as silicon oxide, silicon nitride, or a low-k material such as silicon oxycarbide at the sidewalls and exposed silicon or silicon germanium at the bottom. In alternative embodiments, the contact hole prior to deposition may be lined with a barrier layer, such as WN, MoN, MoC, or TiN onto which the molybdenum metal is deposited.

FIGS. 2A-2C illustrate embodiments of the disclosed methods in which flashes of light irradiate the substrate during the delivery of the precursor during atomic layer deposition or chemical vapor deposition.

FIG. 2A is a representation of the pulse sequence timeline for the delivery of reagents and the light during an atomic layer deposition process.

For the deposition, the metal-containing precursor may be a molybdenum-containing precursor in certain embodiments. Generally, molybdenum precursors may have from two (MoL₂) to six (MoL₆) ligands and can include molybdenum in a wide range of oxidation states ranging from 0 to +6. Molybdenum precursors may also be dimolybdenum compounds having 1) two molybdenum atoms singly or multiply bonded to one another; or 2) two molybdenum atoms connected by a linking group such as a bidentate ligand.

Suitable molybdenum containing precursors include molybdenum halides and oxyhalides, such as fluorides, chlorides, bromides, oxyfluorides, oxychlorides, and oxybromides where molybdenum may be in any of the oxidation states from +2 to +6.

Molybdenum chloride precursors are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

Molybdenum oxyhalide precursors are given by the formula MoO_{y}X_{z}, where X is a halogen (fluorine (F), chlorine (Cl), bromine (Br), or iodine (I)) and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I.

In some embodiments discussed herein, the precursors having molecular weights of less than about 450 g/mol, such as less than about 400 g/mol.

In some embodiments the molybdenum-containing precursor has a formula MoXₙYₘ, wherein X is a chalcogen (e.g., oxygen or sulfur), Y is a halogen (e.g., fluorine, chlorine, bromine, or iodine), n is 0, 1, or 2 and m is 2, 3, 4, 5, or 6. Examples of halogen-containing molybdenum-containing precursors include without limitation MoCl₅, Mo₂Cl₁₀, MoO₂Cl₂, and MoOCl₄. Another example of a halogen-containing molybdenum-containing precursor is MoF₆.

The molybdenum-containing precursor may also be a low valent molybdenum-containing complex. Low valent molybdenum complexes or compounds are those having molybdenum in low oxidation states 0, +1, +2 or +3. In certain embodiments, the low valent molybdenum complexes may be efficacious precursors as it is easier to reduce Mo(I) to Mo(0) or Mo(II)/(III) to Mo(0) than it is to reduce the more commonly utilized Mo(IV)/(V) halide precursors.

Low valent molybdenum precursors may offer a less circuitous surface redox process to obtain fully reduced molybdenum metal films with minimal impurities. Without wishing to be bound by a particular theory, this is likely the result of the ease of reduction of low valent molybdenum precursors.

Mo(0) precursors are advantageous because do not require any reduction steps, and are energetically facile, as their use provides a lower energy barrier to Mo film formation upon exposure to a reducing agent. They are especially amenable in multi-step ALD processes where surface-ligand exchange and conversion (reduction) occurs. Molybdenum hexacarbonyl (Mo(CO)₆) is an example of a molybdenum complex existing in the oxidation state of zero.

A general structure for low valent molybdenum precursors having one molybdenum is MoLₙ (Formula I), and general structures for low valent molybdenum precursors with two molybdenum atoms are Mo₂Lₙ (Formula II) or LₙMo(L′)ₘMoLₙ (Formula III). For any of Formulas I-III, each L is independently a monodentate ligand, ambidentate ligand, bidentate ligand or tridentate ligand and n is an integer of 2 to 6. For Formula III, L′ is a linking moiety such as a bidentate ligand; and m is an integer of 1 to 3.

Suitable ligands for the low valent molybdenum complexes include monodentate ligands, also referred to as unidentate ligands. A monodentate ligand is one which binds or coordinates to a metal center via one coordination site of the metal only, or via one site of the ligand only. They may include a wide variety of substituents such as hydrogen, halo, hydroxy, alkyl silyl, silylalkyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, CO, ═O, ═S, ≡N, ≡CR, ═CR₂, —NO, aralkenyl, aralkyl, sulfonyl, sulfonamido, sulfonimido, carbamate, aryloxyalkyl, carboxyl, carboxy, —C(O)NH(benzyl), amido, azido, isocyanato, thiocyanato, isothiocyanato, cyano, isocyano or cyclyl groups where each R is independently an aliphatic such as haloalkyl or aryl such as a haloaryl group.

In some embodiments, the low valent molybdenum precursors include at least one OR, P(R)₃, CNR, allyl or aryl group, where each R is independently an aliphatic, aryl, haloalkyl or haloaryl group.

In some embodiments, the monodentate ligand can include an oxygen atom. In particular embodiments, one or more ligands can be optionally substituted alkoxy. Non-limiting ligands include, e.g., methoxy, ethoxy, isopropoxy (i-PrO), t-butoxy (t-BuO), and —O—C(CH₃)—CH═C(CH₃)—O— (acac). Non-limiting molybdenum-containing precursors include, e.g., Mo(CH₂F)(t-BuO)₃, Mo(CF₃)(t-BuO)₃, Mo(CH₂I)(t-BuO)₃, Mo(CI₃)(t-BuO)₃, Mo(CH₂CH₂F)(t-BuO)₃, Mo(CH₂CH₂I)(t-BuO)₃, Mo(CH₂F)₂(t-BuO)₂, Mo(CF₃)₂(t-BuO)₂, Mo(CH₂I)₂(t-BuO)₂, Mo(CI₃)₂(t-BuO)₂, Mo(CH₂CH₂F)₂(t-BuO)₂, Mo(CH₂CH₂I)₂(t-BuO)₂, Mo(t-BuO)₂, Mo(CH₃)(t-BuO)₃, Mo(CH₂CH₃)(t-BuO)₃, Mo(CH═CH₂)(t-BuO)₃, Mo(CH═CHCH₃)(t-BuO)₃, Mo(CH₂—CH═CH₂)(t-BuO)₃, Mo(C≡CH)(t-BuO)₃, Mo(C≡CCH₃)(t-BuO)₃, Mo(CH₂C≡CH)(t-BuO)₃, or Mo(acac)₂.

In certain embodiments, the oxygen-containing monodentate ligand may be —OC(CH₃)(CF₃)₂, —OC(CH₃)₂(CF₃), —OC(CH₃)₃, —OSiR₃ (such as —OSiPh₃), C≡O (carbonyl ligand) or —OAr (where Ar groups include but are not limited to phenyl, mesitylenyl, 2,6-iPr₂C₆H₃, hexa-iso-propyl-ter-phenyl, and 2,3,5,6-Ph₄C₆H). In certain embodiments, the oxygen-containing ligand is an ether, epoxide, or ketone. In some cases, the oxygen-containing ligand may be a silyloxy group.

In certain embodiments, the ligand is a phosphorous-containing ligand. Suitable complexes may be of the formula R₃P where R is a halo, aliphatic or aryl group. Examples include secondary or tertiary organophosphines such as P(t-Bu)₃, PMe₃, PPh₃, P(OMe)₃, P(OEt)₃, PCl₃ or PF₃. In some embodiments, the phosphorus containing ligand is phosphanetriyltris(benzene sulfonic acid). Other phosphorus containing ligands include —CH₂P(CH₃)₃, —P(O)OH, —P(O)(OCH₃)₂, —P(O)(OCH₂CH₃)₂, and —CH(Si(CH₃)₃)(P(CH₃)₃).

In some embodiments, the ligand is an isocyano functional group, including isonitriles of the formula —C≡NR, such as isocyanoalkyl, isocyanohaloalkyl, isocyanoaryl, isocyanohaloaryl. In some embodiments, R is an aliphatic group such as a haloalkyl, or an aryl group such as haloaryl. In certain embodiments, R may be —CH₂CF₃, —C(F)═CF₂, —C(F)═C(F)CF₃, —CF₂C(F)═CF₂, —CH(CF₃)₂, —CH(CH₃)(CF₃), or —C(CH₃)₂(CF₃). In certain embodiments, R is a perfluoroalkyl substituent of one to ten carbon atoms such as perfluorinated methyl, ethyl, i-propyl, n-propyl, t-butyl, sec-butyl, n-butyl, cyclopentyl, n-pentyl, cyclohexyl or n-hexyl group.

In some embodiments, the monodentate ligand is one with sp² hybridized character such as an allyl, allenyl, ethenyl, indenyl or cyclopentadienyl group. Two of the same such substituents or two different such substituents may be utilized to form precursors with a sandwich structure. In some embodiments, one such substituent is utilized to form a half-sandwich complex. In certain embodiments, the ligand may be mesitylenyl, tolyl, xylyl, benzyl, anilinyl, N,N-dimethylanilinyl, tetrahydrofuranyl, piperidinyl, pyrrolyl, pyrrolidinyl, pyridinyl, piperidinyl, imidazolyl, or pyrimidinyl.

In some embodiments, the ligand is an atom which is connected directly to molybdenum via a multiple bond such as a double or triple bond. Examples include ═O, ═NR, ═S, ≡N, ═CR₂ or ≡CR, where each R is independently an aliphatic, aryl, haloalkyl or haloaryl group.

In some embodiments, the molybdenum-containing precursor has at least one optionally substituted haloalkyl group. Non-limiting haloaliphatic group ligands include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₋₄ haloalkyl, C₂₋₄ haloalkenyl, and C₂₋₄ haloalkynyl.

In other embodiments, the ligand is an optionally substituted alkyl group, optionally substituted alkenyl, or optionally substituted alkynyl. Non-limiting groups include —CₙH₂ₙ₊₁, in which n is 1 or 2; —CₙH₂ₙ₋₁, in which n is 2, 3, or 4; or —CₙH₂ₙ₋₃, in which n is 2, 3, or 4. Yet other non-limiting groups include methyl (—CH₃), ethyl (—CH₂CH₃), vinyl or ethenyl (—CH═CH₂), 1-propenyl (—CH═CHCH₃), allyl or 2-propenyl (—CH₂—CH═CH₂), 1-butenyl (—CH═CHCH₂CH₃), 2-butenyl (—CH₂CH═CHCH₃), 3-butenyl (e.g. —CH₂CH₂CH═CH₂), ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), 2-methyl-1-propenyl (CH═C(CH₃)₂, isopropenyl (C(CH₃)═CH₂, 1-methylallyl (CH(CH₃)CH═CH₂ and the like.

In some embodiments, the monodentate ligand may be —CH₂P(CH₃)₃, —CH(Si(CH₃)₃)(P(CH₃)₃), —C(O)C₃F₇, or —CHCHSO₂C₆H₅.

In some embodiments, the monodentate ligand includes a sulfur atom. In particular embodiments, one or more monodentate ligands can be —SO₂CF₃, —SO₂C₃N₂H₃, —CHCHSO₂C₆H₅, —SO₂OCH₃, or —SO₂C₆H₄CH₃.

In some embodiments, the monodentate ligand includes a nitrogen atom. In particular embodiments, one or more monodentate ligands can be optionally substituted amino or optionally substituted bis(trialkylsilyl)amino. Non-limiting ligands can include, e.g., —NMe₂, —NEt₂, —NMeEt, —N(t-Bu)-[CHCH₃]₂—N(t-Bu)-(tbba), —N(SiMe₃)₂, and —N(SiEt₃)₂.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, alkyl. In yet other embodiments, the optionally substituted trialkylsilyl is —SiR¹R²R³, in which each R¹, R², and R³ is, independently, alkyl.

In other embodiments, the low valent molybdenum precursor includes a first ligand that is —NR¹R² and a second ligand that is —NR¹R², in which each R¹ and R² is, independently, H or alkyl. In yet other embodiments, the formula includes a first ligand that is —OR¹ and a second ligand that is —OR¹, in which each R¹ is, independently, H or alkyl.

In some embodiments, the monodentate ligand is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, the ligand has at least one beta-hydrogen or beta-halogen.

In some embodiments, at least one monodentate ligand is optionally substituted haloalkyl. Non-limiting haloalkyl groups include, e.g., CₙH_{2n+1-z}X_{z}, wherein n is 1, 2, 3, or greater; wherein z is 1 to 2n+1 (e.g., 1 to 3, 1 to 5, or 1 to 7); and wherein each X is, independently, halo (F, Cl, Br, or I).

In some embodiments, at least one monodentate ligand is optionally substituted alkenyl or optionally substituted alkynyl. Non-limiting alkenyl groups include, e.g., CₙH₂ₙ₋₁, where n is 2, 3, 4, or greater, such as ethenyl, 1-propenyl, 2-propenyl, 1-butenyl, 2-butenyl, or 3-butenyl. Non-limiting alkynyl groups include, e.g., CₙH₂ₙ₋₃, where n is 2, 3, 4, or greater, such as ethynyl, 1-propynyl, 2-propynyl, 1-butynyl, 2-butynyl, or 3-butynyl.

Alkynyl groups are also suitable monodentate ligands in certain embodiments. In some embodiments, the carbon-carbon triple bond is not bound directly to the molybdenum, for example in a formula R¹CCCH₂MoL₃ where R¹ is a C₁-C₂ linear or branched alkane such as methyl or ethyl; and L is an amino (dimethylamino, diethylamino, ethylmethylamino, methylpropylamino, aminiocyclopentane, aminocyclohexane) or alkoxy group (methoxy, ethoxy, n-propoxy, isopropoxy, t-butoxy, sec-butoxy, or n-butoxy).

Alkyne compounds which have a carbon-carbon triple bond directly bonded to the molybdenum atom will hydrolyze in the presence of water similar to, although much slower than, amino and alkoxy groups. Therefore, compounds such as (R¹C≡C)₃MoR² and (R¹C≡C)₄Mo where R¹ is a simple alkane such as methyl or ethyl, and R² is a C₁-C₂ hydrocarbon are precursors having monodentate ligands in accordance with certain embodiments. In compound (R¹C≡C)₃MoR² the molybdenum center has three alkynes with the carbon-carbon triple bond bonded to the molybdenum center. Tetra-alkynes such as those shown for (R¹C≡C)₄Mo.

In some embodiments, the monodentate ligand is halo. In particular, the metal-containing precursor can be a metal halide or organometal halide. Non-limiting metal halides and organometal halides include FCH₂MoX₃, CF₃MoX₃, ICH₂MoX₃, CI₃MoX₃, CH₂FCH₂MoX₃, CH₂ICH₂MoX₃, MoX₂, or MoX₄, in which each X is, independently, halo. In other embodiments, the metal-containing precursor is RMoX₃, in which R is C₁₋₄ haloalkyl, C₂₋₄ haloalkenyl, or C₂₋₄ haloalkynyl; and in which each X is, independently, halo. In yet other embodiments, the metal-containing precursor is RMoX₃, in which R is C₁₋₂ alkyl, C₂₋₄ alkenyl, or C₂₋₄ alkynyl; and in which each X is, independently, halo.

In other embodiments, the monodentate ligand is C₁-C₃ aliphatic (wherein the C₁-C₃ aliphatic may be optionally substituted with a ketone, an alkoxy group, an epoxy group) or a —C(O)C₁-C₃ alkyl group. Ethers, ketones or epoxide-containing ligands on the low valent molybdenum-containing precursors may be advantageous to assist in crosslinking.

In some embodiments, the monodentate ligand can include a silicon atom. In some embodiments, the monodentate ligand may be —Si(CH₃)₃, —Si(C₂H₅)₃, —CH₂Si(CH₃)₃, —CH(Si(CH₃)₃)₂ or —C(Si(CH₃)₃)₃. In particular embodiments, one or more ligands can be optionally substituted trialkylsilyl or optionally substituted bis(trialkylsilyl)amino. Non-limiting ligands can include, e.g., —SiMe₃, —SiEt₃, —N(SiMe₃)₂, and —N(SiEt₃)₂.

In some embodiments, the monodentate ligand includes at least one isocyanato, isocyanoalkyl, isocyanohaloalkyl, isocyanoaryl, isocyanohaloaryl, alkoxy or haloalkoxy.

In some embodiments, the monodentate ligand is at least one allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl or pyrimidinyl.

For any formula herein, each monodentate ligand may independently be hydrogen, halo, azido, cyano, akylcarbonyl, isothiocyanato, thiocyanato, optionally substituted alkyl, optionally substituted aryl, optionally substituted amino, optionally substituted bis(trialkylsilyl)amino, optionally substituted trialkylsilyl, or optionally substituted alkoxy (e.g., —OR¹, in which R¹ can be alkyl).

The present disclosure also encompasses hydrogen as a monodentate ligand. An example of a complex having a hydrogen monodentate ligand is a molybdenum hydride precursor such as Mo(Cp)₂H₂, where Cp is cyclopentadienyl.

The monodentate ligand may be an ambidentate ligand, which has two potential donor atoms, but only attaches to a metal via one of the two. In certain embodiments, the ambidentate ligand is NO₂⁻, which may bond to a metal through either the nitrogen atom or the oxygen atom.

Suitable ligands for the low valent molybdenum complexes include bidentate ligands. A bidentate ligand (also referred to as a chelating ligand) is one which binds or coordinates to a metal center via two coordination sites of the metal, or via two sites of the ligand. Bidentate ligands are Lewis bases that donate two pairs of electrons to a metal atom. The bidentate ligands may be neutral or anionic. Furthermore, the bidentate ligands may have the same two coordination atoms, or may be unsymmetrical bidentate ligands, where the two coordination atoms are not the same. In some embodiments, the bidentate ligands may be ethylenediamine (en), bipyridyl (bpy), 1,2-bis(dimethylphosphino)ethane (dmpe), phenanthroline (phen), 1,2-bis(diphenylphosphino)ethane (dppe), acetate (OAc), oxalate (ox), or acetylacetonate (acac).

The bidentate ligand may be a linking moiety L′ of the structure -(E)ₑ- where each E independently includes NR, C(R)ₙ, Si(R)ₙ, S, O or P(R)ₙ; each R independently includes hydrogen, aryl, amino or aliphatic; n is 0, 1 or 2 and e is 1, 2, 3, 4 or 5.

Suitable low valent molybdenum precursors may contain one, two or three bidentate ligands each of which may be the same or different.

The bidentate ligand may be an amidinate, an amidate, an iminopyrrolidinate, a diazabutadiene, a beta-imino amide, an alpha-imino alkoxide, a beta-diketiminate, a beta-ketoiminate, a beta-diketonate, a pyrazolate, a beta-amino alkoxide, a guanidinidate, a dithiolene, an alpha-iminothiolene, an alpha-dithiolate, or a beta-dithiolate. Other examples of suitable materials include the bidentate ligands described in US 2022/0170155 and WO 2021/035236, which are incorporated herein by reference in their entireties.

A tridentate ligand is one with three atoms that can function as acceptors in a coordination complex. In certain embodiments, the tridentate ligand three nitrogen, three sulfur, three phosphorus or three oxygen atoms available for chelation. Tridentate ligands include cis, cis-1,3,5-triaminocyclohexane, 1,4,7-triazacyclononane, 1,4,7, -trimethyl-1,4,7-triazacyclononane, 1,4,7-trithiacyclononane, bis(diphenylphosphinoethyl)phenylphosphine, N,N,N′,N″N″-pentamethyldiethylenetriamine, tris(4S-isopropyl-2-oxazolinyl)phenylborate, tris(4,4-dimethyl-2-oxazolinyl)phenyl borate, trispyrazolylborate, 1,4,7-trioxonane, diethylenetriamine, or an iminodiacetate anion. Suitable low valent molybdenum precursors may contain one, two or more tridentate ligands which may be the same or different.

The low valent molybdenum precursors may have two to six ligands. Each occurrence of L may independently be a monodentate, ambidentate, bidentate or tridentate ligand as described above. Low valent molybdenum precursors having two ligands may be of the formula MoL₂. Example structures for molybdenum precursors having three ligands (Formula XIV),

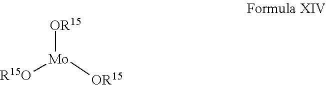

four ligands (Formula V and Formula VI)

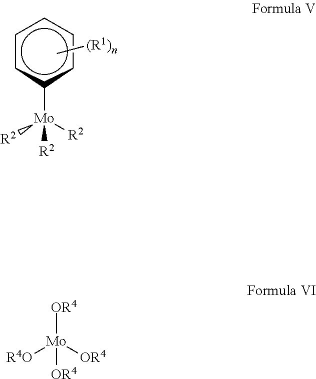

or five ligands (Formula IX and Formula X)

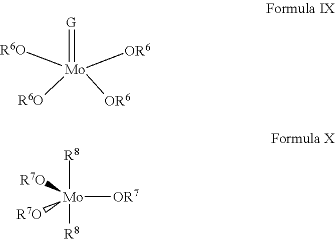

in certain embodiments. For Formulas XIV, VI, IX and X, R⁴, R⁶, R⁷ and R¹⁵ are each independently —CH₃, —C₂H₅, —C₃H₇, —C₄H₉, —C₅H₁₁, —CF₃, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃ or —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃, or —SO₂C₆H₄CH₃. For Formula IX, G may be ═O, ═NR, ═S or ═CR₂, where each R is independently an aliphatic, aryl, haloalkyl or haloaryl group. For Formula X, each R⁸ is independently any of the monodentate, ambidentate or bidentate ligands described above. For Formula V, R¹ may be aliphatic, R² may be any of the monodentate, ambidentate, bidentate or tridentate ligands described above, and n may be 1, 2, 3, 4 or 5.

Low valent molybdenum precursors may also have six ligands. Such precursors may have the general formula Mo(X)ₚ(R¹⁰)_{q} (XII) where each X independently includes chloro, fluoro, bromo or iodo; each R¹⁰ independently includes allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹¹, where R¹¹ includes aliphatic, aryl or heterocyclyl; p is 1 to 4; q is 2 to 5; and p+q=6.

Low valent molybdenum precursors having six ligands may also be of the Formula (XIII): Mo(R¹²)ᵣ(R¹³)ₛ (XIII) where each R¹² independently includes allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹⁴, where R¹⁴ includes aliphatic, aryl or heterocyclyl; each R¹³ independently includes trimethylphosphine, triethylphosphine, tri-i-propyl phosphine, triphenylphosphine, tris(trimethylsilyl)phosphine, tris(2-carboxyethyl)phosphine, tris(dimethylamino)phosphine, tris(o-tolyl)phosphine, tris(4-methoxyphenyl)phosphine or tris(2-furyl)phosphine; r is 1 to 6; s is 0 to 5; and r+s=6.

Structures for low valent molybdenum precursors may have six ligands. In some embodiments, the precursors may have one or more CNR ligands which may be isocyanoalkyl, isocyanohaloalkyl, isocyanoaryl, or isocyanohaloaryl groups. In some embodiments, R is an aliphatic group such as a haloalkyl, or an aryl group such as haloaryl. In certain embodiments, R may be —CH₂CF₃, —CH(CF₃)₂, —CH(CH₃)(CF₃), or —C(CH₃)₂(CF₃). In certain embodiments, R is a perfluoroalkyl substituent of one to ten carbon atoms such as perfluorinated methyl, ethyl, i-propyl, n-propyl, t-butyl, sec-butyl, n-butyl, cyclopentyl, n-pentyl, cyclohexyl or n-hexyl group. In some embodiments, the structures may have one or more PMe₃ ligands.

Molybdenum complexes can be prepared using a zero valent starting material such as molybdenum hexacarbonyl. Other synthetic routes include reaction of MoCl₃(THF)₃ with the appropriate ligand followed by reduction and reaction of MoX₅ (X=Cl, Br, I) with the appropriate ligand followed by reduction.

The starting material can be treated with a neutral ligand, such as a thioether (dialkylsulfide), to induce redox neutral ligand exchange. The zero valent starting material can also be treated with a ligand precursor, such as bis(diethylthiocarbamoyl)disulfide or bis(trifluoromethyl)-1,2-dithiete, to induce oxidative addition and form the sulfur-containing complexes described herein.

The reactions may be conducted in a variety of non-protic solvents. For example, the reaction may be conducted in an ether solvent, such as tetrahydrofuran, 2-methyltetrahydrofuran, diethyl ether, methyl-tert-butyl ether, 1,2-dimethoxyethane, in a hydrocarbon solvent such as toluene, benzene, heptane, hexane, pentane, or in a halocarbon solvent such as chlorobenzene, dichlorobenzene, fluorobenzene, difluorobenzene, dichloromethane, chloroform, etc. The reactions can be conducted in a wide temperature range depending on the boiling point of the solvent and on solubility of the products. In some embodiments, the starting materials, reaction intermediates, and the desired products are unstable toward moisture and oxygen. Accordingly, the reaction process should be conducted using anhydrous and air-free conditions using a protective inert gas, such as nitrogen or argon.

In another aspect, precursors for deposition of molybdenum-containing films are dimolybdenum compounds containing a direct molybdenum-molybdenum bond (e.g., a multiple molybdenum-molybdenum bond, such as a double bond, or any multiple bond with a bond order of 2-5). The directly bonded dimolybdenum precursors may be of the structure Mo₂Lₙ (II), where each occurrence of L is independently a monodentate, ambidentate, bidentate or tridentate ligand as described above, and n is 2 to 6. One example precursor is Mo₂(O-isopropyl)₆. In some embodiments, the dimolybdenum precursor has molybdenum atoms directly connected by a double bond. In some embodiments, the dimolybdenum precursor has molybdenum atoms directly connected by a triple bond. L may be any ligand described above, or may be any one of CO, CNR or PMe₃ (where R is aliphatic, aryl or heterocyclyl). Such precursors are particularly useful for deposition of molybdenum metal and high purity molybdenum metal because it may be easier to reduce such compounds to metallic molybdenum than some monoatomic molybdenum compounds.

Dimolybdenum precursors described herein can be synthesized using dimolybdenum tetraacetate as a starting material by treatment with a ligand salt such as lithium amidate. In one aspect, a container housing any of the precursors described herein in a solid or liquid form is provided. In another aspect a solution of any of these precursors is provided, where the solvent may include, for example, a high boiling point hydrocarbon solvent, such as a higher alkane. In some embodiments a container holding the molybdenum precursor (in solid or liquid form or in solution) is filled with an inert gas, such as nitrogen (N₂), or argon (Ar), to prevent contact of the precursor with air, and possible decomposition due to contact with moisture and/or air. In some embodiments the container is adapted for vaporization of the precursor inside the container. For example, the container may include an inlet and an outlet, where the inlet is adapted to be connected with a source of a carrier gas that can be flowed over or through the precursor thereby assisting in precursor vaporization. The outlet is adapted for removing the carrier gas and the precursor vapor from the container and is configured to be connected to a conduit that can be used to deliver the precursor vapor to the processing chamber. The inlet and the outlet each has a closed position and an open position, and, for example, can include manual valves that can be used to switch from closed to open positions and back. When the container is stored or transported the inlet and the outlet are closed. When the container is fitted to the deposition apparatus for use, the inlet and the outlet valves may be open, and a carrier gas may be flown into the inlet, and out from the outlet carrying the precursor vapor.

In some embodiments the container has a flow-over design, in which the inlet and the outlet are positioned above the surface of the precursor. For example, in a cylindrical container the inlet and the outlet may be positioned at a similar vertical elevation (e.g., the vertical distance between the inlet and the outlet may be less than about 20% of the cylinder height). In other embodiments the container has a bubbler design, in which the inlet is positioned below the surface of the precursor and the outlet is positioned above the inlet (e.g., above the surface of the precursor). For example, in a cylindrical container the inlet and the outlet may be positioned far from each other in a vertical direction (e.g., the vertical distance between the inlet and the outlet may be more than about 30%, such as more than about 50%, or more than about 80% of the cylinder height.

A low valent dimolybdenum complex may also contain two molybdenum atoms connected indirectly to each other by a linking moiety. Such precursors may be of the formula LₙMo(L′)ₘMoLₙ (III) where each L is independently a monodentate ligand, ambidentate ligand, bidentate ligand, or tridentate ligand as described above; L′ is a linking moiety: n is 2 to 6; and m is 1 to 3. The linking moiety L′ may be of the structure -(E)ₑ- where each E independently includes C(R)ₙ, NR, Si(R)ₙ, S, O or P(R)ₙ; each R independently includes hydrogen, aryl, amino or aliphatic; n is 0, 1 or 2 and e is 1, 2, 3, 4 or 5.

In some embodiments, the low valent dimolybdenum complex may contain two molybdenum atoms both directly bonded to each other and also connected indirectly to each by a linking moiety as described above.

In some embodiments, the bidentate ligand has a structure of Formula (IV): -(E)ₑ- (IV), wherein each E is independently NR, C(R)ₙ, Si(R)ₙ, S, O or P(R)ₙ; where each R is independently hydrogen, aryl, amino or aliphatic; e is 1, 2, 3, 4 or 5; and n is 0, 1 or 2.

In some embodiments, the bidentate ligand is —O(C(R)ₙ)ₘO—, —O(C(R)ₙ)ₘNR—, —C(R)₂P(R)₂C(R)₂P(R)₂—C(R)₂— or —C(R)₂P(R)₂N(R)P(R)₂—C(R)₂—: where each R is independently H, aliphatic, haloalkyl, alkylsilyl, alkylamino, amino or alkoxy, or R groups may be linked to form a ring; n is 0, 1 or 2; and m is 1, 2 or 3.

In some embodiments, the low valent molybdenum precursor has a structure of formula MoL₄.

In some embodiments, the low valent molybdenum precursor has one or two bidentate ligands.

In some embodiments, the low valent molybdenum precursor has a structure of Formula (V):

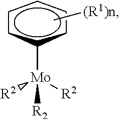

wherein each R¹ independently comprises alkyl or haloalkyl; each R² independently comprises carbonyl, cyano, isocyanoalkyl, isocyanohaloalkyl, isocyanoaryl, isocyanohaloaryl, isocyanato, or isothiocyanato; and n is 0, 1, 2 or 3.

In some embodiments, each R² independently is —CNR³, and where R³ comprises aliphatic, aryl or heterocyclyl.

In some embodiments, R³ is haloalkyl or haloaryl.

In some embodiments, R³ is pentafluoroethyl, heptafluoro-n-propyl, pentafluorobenzyl, —CF₃, —C₄F₉, —C₅F₁₁, —CH₂CF₃, —CH(CF₃)₂, —C(F)═CF₂, —C(F)═C(F)CF₃, —CF₂C(F)═CF₂, —CH(CH₃)(CF₃), —C(CH₃)₂(CF₃), —C(CF₃)₃ or nonafluoro-n-butyl.

In some embodiments, the low valent molybdenum precursor has a structure of Formula (VI)

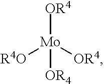

where each R⁴ is independently aliphatic, alkylsilyl, or haloalkyl; or R⁴ substituents may be linked to form a ring.

In some embodiments, each R⁴ is independently —CH₃, —C₂H₅, —C₃H₇, —C₄H₉, —C₅H₁₁, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃.

In some embodiments, the low valent molybdenum precursor has a structure of Formula (VII):

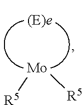

where each E independently comprises NR, C(R)ₙ, Si(R)ₙ, S, O or P(R)ₙ, where each R independently comprises hydrogen, aryl, amino or aliphatic; each R⁵ independently comprises halo, hydroxy, aliphatic, alkyl silyl, alkenyl, alkynyl, allyl, alkoxy, alkenoxy, alkynoxy, thioalkoxy, aliphatic acyl, —CF₃, nitro, amino, imino, —N(C₁-C₃ alkyl)C(O)(C₁-C₃ alkyl), —N(Si(CH₃)₃)₂, —C₁-C₃ alkylamino, alkenylamino, alkynylamino, di(C₁-C₃ alkyl)amino, —C(O)O—(C₁-C₃ alkyl), —C(O)NH—(C₁-C₃ alkyl), —CH═NOH, —P(C₁-C₃ alkyl)₃, —PO₃H₂, —OPO₃H₂, —C(O)N(C₁-C₃ alkyl)₂, haloalkyl, alkoxycarbonyl, alkoxyalkoxy, carboxaldehyde, carboxamide, cycloalkyl, cycloalkenyl, cycloalkynyl, aryl, aroyl, aryloxy, arylamino, biaryl, thioaryl, heterocyclyl, alkylheterocyclyl, heterocyclylalkyl, heterocycloyl, alkylaryl, alkylcarbonyl, ═O, ═S, —CO, aralkenyl, aralkyl, sulfonyl, sulfonamido, carbamate, aryloxyalkyl, carboxyl, carboxy, —C(O)NH(benzyl), amido, azido, isocyanato, isocyanoalkyl, isocyanohaloalkyl, isocyanoaryl, isocyanohaloaryl, thiocyanato, isothiocyanato, cyano or cyclyl; e is 1, 2, 3, 4 or 5; and n is 0, 1 or 2.

In some embodiments, the low valent molybdenum precursor has a structure of Formula (VIII):

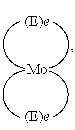

where each E independently comprises NR, C(R)ₙ, Si(R)ₙ, S, O or P(R)ₙ; where each R independently comprises hydrogen, aryl, amino or aliphatic; e is 1, 2, 3, 4 or 5; and n is 0, 1 or 2.

In some embodiments, the low valent molybdenum precursor has a structure of formula MoL₅.

In some embodiments, the low valent molybdenum precursor has one bidentate ligand or two bidentate ligands.

In some embodiments, the bidentate ligand has a structure of Formula (IV): -(E)ₑ- (IV), wherein each E is independently NR, C(R)ₙ, Si(R)ₙ, S, O or P(R)ₙ; where each R is independently hydrogen, aryl, amino or aliphatic; e is 1, 2, 3, 4 or 5; and n is 0, 1 or 2.

In some embodiments, the bidentate ligand is —O(C(R)ₙ)ₘO—, —O(C(R)ₙ)ₘNR—, —C(R)₂P(R)₂C(R)₂P(R)₂—C(R)₂— or —C(R)₂P(R)₂N(R)P(R)₂—C(R)₂—; where each R is independently H, aliphatic, haloalkyl, alkylsilyl, alkylamino, amino or alkoxy, or R groups may be linked to form a ring; n is 0, 1 or 2; and m is 1, 2 or 3.

In some embodiments, the low valent molybdenum precursor has two bidentate ligands.

In some embodiments, the low valent molybdenum precursor has a structure of Formula (X) or Formula (XI):

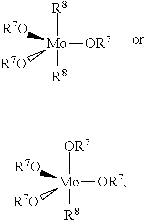

where each R⁷ is independently —CH₃, —C₂H₅, —C₃H₇, —C₄H₉, —C₅H₁₁, —CF₃, —C(F)═CF₂, C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃; and each R⁸ is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR⁹, where R⁹ is aliphatic, aryl or heterocyclyl.

In some embodiments, R⁹ comprises haloalkyl or haloaryl.

In some embodiments, R⁹ is pentafluoroethyl, heptafluoro-n-propyl, pentafluorobenzyl, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃ or nonafluoro-n-butyl.

In some embodiments, the low valent molybdenum precursor has a structure of formula MoL₆.

In some embodiments, the low valent molybdenum precursor has one, two or three bidentate ligands.

In some embodiments, the bidentate ligand has a structure of Formula (IV): -(E)ₑ- (IV), where each E is independently NR, C(R)ₙ, Si(R)ₙ, S, O or P(R)ₙ; where each R is independently hydrogen, aryl, amino or aliphatic; e is 1, 2, 3, 4 or 5; and n is 0, 1 or 2.

In some embodiments, the bidentate ligand is —O(C(R)ₙ)ₘO—, —O(C(R)ₙ)ₘNR—, —C(R)₂P(R)₂C(R)₂P(R)₂—C(R)₂— or —C(R)₂P(R)₂N(R)P(R)₂—C(R)₂—; where each R is independently H, aliphatic, haloalkyl, alkylsilyl, alkylamino, amino or alkoxy, or R groups may be linked to form a ring; n is 0, 1 or 2; and m is 1, 2 or 3.

In some embodiments, the low valent molybdenum precursor has a structure of Formula (XII): Mo(X)ₚ(R¹⁰)_{q} (XII), where each X is independently chloro, fluoro, bromo or iodo; each R¹⁰ is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹¹, where R¹¹ is aliphatic, aryl or heterocyclyl; p is 1, 2, 3 or 4; q is 2, 3, 4 or 5; and p+q=6.

In some embodiments, R¹¹ is haloalkyl or haloaryl.

In some embodiments, R¹¹ is pentafluoroethyl, heptafluoro-n-propyl, pentafluorobenzyl, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃ or nonafluoro-n-butyl.

In some embodiments, the low valent molybdenum precursor has a structure of Formula (XIII): Mo(R¹²)ᵣ(R¹³)ₛ (XIII), where each R¹² is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹⁴, where R¹⁴ is aliphatic, aryl or heterocyclyl; each R¹³ is independently trimethylphosphine, triethylphosphine, tri-i-propyl phosphine, triphenylphosphine, tris(trimethylsilyl)phosphine, tris(2-carboxyethyl)phosphine, tris(dimethylamino)phosphine, tris(o-tolyl)phosphine, tris(4-methoxyphenyl)phosphine or tris(2-furyl)phosphine; r is 1, 2, 3, 4, 5 or 6; s is 0, 1, 2, 3, 4 or 5; and r+s=6.

In some embodiments, R¹⁴ is haloalkyl or haloaryl.

In some embodiments, R¹⁴ is pentafluoroethyl, heptafluoro-n-propyl, pentafluorobenzyl, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃ or nonafluoro-n-butyl.

In some embodiments, the low valent molybdenum precursor has a structure of formula MoL₂.

In some embodiments, each L is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, or pyrimidinyl.

In some embodiments, the low valent molybdenum precursor has a structure of formula MoL₃.

In some embodiments, the low valent molybdenum precursor has one bidentate ligand.

In some embodiments, the low valent molybdenum precursor is a structure of Formula (XIV):

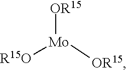

where each R¹⁵ is independently aliphatic, alkylsilyl or haloalkyl; or R¹⁵ substituents may be linked to form a ring.

In some embodiments, each R¹⁵ is independently —CH₃, —C₂H₅, —C₃H₇, —C₄H₉, —C₅H₁₁, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃.

In some embodiments, the low valent molybdenum precursor has a structure of Formula (XV): Mo₂(OR¹⁶)₆ (XV), where each R¹⁶ is independently aliphatic.

In some embodiments, the molybdenum-containing layer is molybdenum metal.

In some embodiments, the molybdenum-containing layer is molybdenum nitride, molybdenum carbide, molybdenum boride, molybdenum silicide or a combination thereof.

In some embodiments, the molybdenum-containing layer is a molybdenum-containing film.

In some embodiments, the at least one reactant is hydrogen, ammonia, diborane, water, hydrogen sulfide, a thiol, an alcohol, an amine, hydrazine, silane or disilane.

The present disclosure includes a metal coordination complex. In some embodiments, the complex has a structure of Formula (V):

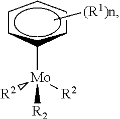

wherein each R¹ is independently alkyl or haloalkyl; each R² is independently carbonyl, cyano, isocyanoalkyl, isocyanohaloalkyl, isocyanoaryl, isocyanohaloaryl, isocyanato or isothiocyanato; and n is 0, 1, 2 or 3.

The present disclosure also includes certain metal coordination complexes. In some embodiments, the complex has a structure of Formula (VI), Formula (IX), Formula (X), Formula (XI), or Formula (XV):

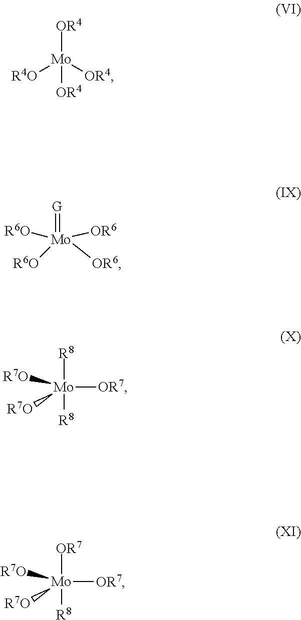

or
Mo₂(OR¹⁶)₆ (XV), where R⁴, R⁶, R⁷ and R¹⁶ are each independently —CH₃, —C₂H₅, —C₃H₇, —C₄H₉, —C₅H₁₁, —CF₃, —C(F)═CF₂, —C(F)═C(F)CF₃, —CF₂C(F)═CF₂, —C₄F₉, —C₅F₁₁, —CH₂CF₃, —CH(CF₃)₂, —CH(CH₃)(CF₃), —C(CH₃)₂(CF₃), —C(CF₃)₃, —Si(CH₃)₃, —Si(C₂H₅)₃, —CH₂Si(CH₃)₃, —CH(Si(CH₃)₃)₂, —C(Si(CH₃)₃)₃, —P(CH₃)₃, —CH₂P(CH₃)₃, —P(O)OH, —P(O)(OCH₃)₂, —P(O)(OCH₂CH₃)₂, —CH(Si(CH₃)₃)(P(CH₃)₃), —SO₂CF₃, —SO₂C₃N₂H₃, —C(O)C₃F₇, —CHCHSO₂C₆H₅, —SO₂OCH₃ or —SO₂C₆H₄CH₃; G is ═O, ═NR, ═S or ═CR₂, where each R is independently an aliphatic, aryl, haloalkyl or haloaryl group; and each R⁸ is independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR⁹, where R⁹ is aliphatic, aryl or heterocyclyl.

The present disclosure includes other metal coordination complexes. In some embodiments, the complex has a structure of Formula (XII) or Formula (XIII): Mo(X)ₚ(R¹⁰)_{q} (XII) or Mo(R¹²)ᵣ(R¹³)ₛ (XIII), where each X is independently chloro, fluoro, bromo or iodo; where R¹⁰ and R¹² are each independently allyl, allenyl, ethenyl, mesitylenyl, tolyl, xylyl, benzyl, cyclopentadienyl, indenyl, anilinyl, N,N-dimethylanilinyl, tetrahydrofuranyl, piperidinyl, pyrrolyl, pyrrolidinyl, pyridinyl, piperidinyl, imidazolyl, pyrimidinyl, —NO, —CO, —P(CH₃)₃, —P(CH₂CH₃)₃ or —CNR¹⁴, where R¹⁴ is aliphatic, aryl or heterocyclyl; each R¹³ is independently trimethylphosphine, triethylphosphine, tri-i-propyl phosphine, triphenylphosphine, tris(trimethylsilyl)phosphine, tris(2-carboxyethyl)phosphine, tris(dimethylamino)phosphine, tris(o-tolyl)phosphine, tris(4-methoxyphenyl)phosphine or tris(2-furyl)phosphine; p is 1, 2, 3 or 4; q is 2, 3, 4 or 5; p+q=6; r is 1, 2, 3, 4, 5 or 6; s is 0, 1, 2, 3, 4 or 5; and r+s=6; with the proviso that at least one R¹⁰ of Formula (XII) is —CNR¹⁴, and with the proviso that at least one R¹² of Formula (XIII) is —CNR¹⁴.

The molybdenum-containing films, and, particularly, high purity molybdenum metal, provided herein can be used in interconnect metallization (e.g., for filling recessed features to form contacts), in logic gate applications in FinFETs, as adhesion layers or diffusion barriers, and in 3D NAND fabrication. Examples of applications include logic and memory contact fill, DRAM buried wordline fill, vertically integrated memory gate, and wordline fill, and 3-D integration using through-silicon vias (TSV). The resistivity of molybdenum scales better than that of tungsten, and in some embodiments, molybdenum is particularly advantageous metal for filling narrow recessed features, e.g., features with widths of less than about 20 nm.

In one application, molybdenum metal is used for manufacturing barrierless contacts. In this application, molybdenum metal is deposited directly into the recessed features (contact holes) having widths of about 5-100 nm, e.g., about 5-20 nm, where the recessed features are formed in the dielectric layer, and include exposed dielectric, such as silicon oxide, silicon nitride, or a low-k material such as silicon oxycarbide at the sidewalls and exposed silicon or silicon germanium at the bottom. In alternative embodiments, the contact hole prior to deposition may be lined with a barrier layer, such as WN, MoN, MoC, or TiN onto which the molybdenum metal is deposited.

Besides molybdenum, the methods are applicable to deposition of other metals including ruthenium and tungsten. Ruthenium metal can be deposited, for example, using vaporizable ruthenium precursors, such as bis(ethylcyclopentadienyl)ruthenium (II), bis(pentamethylcyclopentadienyl)ruthenium, ruthenocene, and cyclopentadienylpropylcyclopentadienylruthenium (II).

Tungsten can be deposited using a variety of volatile precursors. In some embodiments halogen-containing tungsten precursors, such as WHalₓ, where Hal is a halogen (e.g., F, Cl, Br, and/or I) and x is from 2 to 6, are used. In some embodiments tungsten chloride is used. Tungsten chloride includes tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride may be used.

In some embodiments, other useful precursors include vanadium-containing precursors such as tetrakis(dimethylamino)vanadium, tris(dimethylamino)cyclopentadienylvanadium, tetrakis(ethylmethylamino)vanadium; niobium-containing precursors such as (tert-butylimido)bis(diethylamino)niobium, (tert-butylimido)bis(dimethylamino)niobium and (tert-butylimido)bis(ethylmethylamino)niobium; tantalum-containing precursors as tert-butylimidotris(dimethylamido)tantalum and tantalum pentachloride; iron-containing precursors such as iron (III) tert-butoxide dimer, ferrocene and iron pentacarbonyl; nickel-containing precursors such as allyl(cyclopentadienyl)nickel(II) and nickel(II) bis(acetylacetonate); zinc-containing precursors such as zinc acetate and diethylzinc; and chromium-containing precursors such as chromium carbonyl and bis(cyclopentadienyl)chromium (II).

Returning to FIG. 2A, the flash enhanced no-purge atomic layer deposition cycle begins with delivery of a pulse of a molybdenum-containing precursor such as MoCl₅ or MoO₂Cl₂ while a process chamber temperature is maintained at 450° C. or less. In some embodiments, the temperature within the process chamber is 400° C. or less. During the introduction of the precursor into the processing chamber, the substrate is contacted with light from a light source. As illustrated, the duration of the contact with light is shorter than the duration of the precursor introduction and may occur at the beginning, at the middle of, or during the end of precursor introduction.

In some embodiments, irradiation of the substrate with light particularly enhances the nucleation phase of metal-on-dielectric growth of deposited metal. Without wishing to be bound by theory, the thermal pulse from a flash lamp provides a visible and near IR range of light which only negligibly causes photolytic decomposition of metal precursors in the gas phase before they reach the target substrate. Short-term (rapid) and direct heating of only the substrate surface allows for thermal activation of the dielectric (such as silicon oxide) material's surface and subsequent chemical reaction of the precursor without heating the underlying bulk material.

The flash lamp or lamps may be modulated or pulsed every pre-determined number of microseconds (i.e.—every 30 μs). In certain embodiments, the light source (flash lamp) is a 100 μs pulsed light source providing 8 Joules (J) of lamp power per centimeter squared (cm²) with a 1 Hz cycle. In other embodiments, the pulsed light source provides 7 J/cm² or less of energy for a duration of about 0.3 seconds. The irradiation time for contacting the substrate with flashes of light may be 100 milliseconds or less. In certain embodiments, the irradiation time is 1 millisecond or more and 10 milliseconds or less. In other embodiments, the irradiation time is 0.2 microseconds or more and 10 milliseconds or less.

The light source is utilized to create a brief higher temperature (also described as a transitory elevated temperature) at the top surface and/or nucleation layer of a semiconductor substrate than in the bulk. The nucleation layer is typically the upper 5 to 10 percent of the thickness of a substrate; or about 10 to 12 angstroms in from the top surface. The remaining portion of the substrate below the top surface and nucleation layer (90 to 95% of the overall thickness) is referred to as the bulk.

Use of a light source as described herein may allow a transient temperature difference between the surface and the bulk of the substrate of from about 50° C. to about 250° C. In some embodiments, the temperature at the surface of the substrate is about 500° C. or more; meanwhile the bulk of the semiconductor remains at a temperature of 450° C. or less. Since nucleation typically does not occur at temperatures below 500° C., the use of a light source to create the appropriate nucleation temperature without the necessity of heating the entire substrate and/or process chamber is advantageous.

Furthermore, the wavelength of light utilized can be tuned to the particular precursor utilized for metal deposition. Light may be within a wavelength range of from 400 to about 110 nm. In some embodiments, when the metal precursor is MoO₂Cl₂, wavelengths of 200 to 260 nm may be appropriate. If a mixture of precursors is utilized, or two different precursors are introduced sequentially, each may have different molar absorptivity coefficients, necessitating use of more than one wavelength of light. Single or in some cases multiple flashes may be required depending on the length of the precursor dose.

After the precursor introduction and contact with light, a reducing agent may be introduced into the processing chamber.

The reducing agent is typically a reducing gas and may be photoactive either alone or in combination with other chemical species present in the processing chamber. Suitable examples of reducing agents include H₂, SiH₄, NH₃, or NH₃-like compounds where the H is replaced by deuterium (e.g. NH₂D, NHD₂ or ND₃); hydrazine (N₂H₄) or other photoreactive gases that can produce an H radical such as tetramethylsilane, trimethylsilane, amines (methyl-, dimethyl- or trimethylamine or ethylamine); alkenes such as ethylene or propylene, or alkynes such as acetylene or combinations which may additionally include an inert gas or inert gas combinations. The inert gas may be He, N₂ or Ar.

In some embodiments, the reducing agent is hydrogen, ammonia, hydrazine, silane, disilane, trisilane, germane, digermane, diborane or a combination thereof.

Exposing the substrate to the reducing agent may include contacting the substrate with the reducing agent for a time of between about 0.1 seconds and about 180 seconds; between about 0.5 seconds and 60 seconds; or between about 0.1 seconds at 10 seconds. The flow rate of the reducing agent during the exposure of the substrate may be less than 30 slm, or less than 15 slm, or less than 10 slm, or less than 5 slm, or less than 2 slm or even less than 0.1 slm in some embodiments. The flow rate of the reducing agent may range from about 0.1 to 30 slm, from about 5 to 15 slm, or equal to or greater than 10 slm.

This cycle may be repeated as many times as necessary to deposit a desired amount of metal. In some instances, greater than 50 cycles may be performed for a single recipe within a single process chamber. In the case where the recessed feature is uniformly dielectric (SiO₂ for example) only a liner of molybdenum (Mo) metal or sparse nucleation of Mo islands is required for subsequent growth of Mo and therefore few cycles may be required than if there was no flash enhancement. Furthermore, the surface-to-bulk heat dissipation will rapidly increase as film closure occurs and Mo-on-dielectric growth transitions to Mo-on-Mo growth. The number of cycles of flash enhanced processes may require adjustment, or cycles may be ended in certain embodiments once a desired amount of Mo-on-Mo growth is deposited.

FIG. 2B is a representation of another embodiment of the method; a flash enhanced atomic layer deposition in which light irradiates a substrate during precursor delivery and which includes purge steps. The method is similar to that described in FIG. 2A above in terms of the applicable precursors, light sources, reducing agents and process conditions, but also includes purging of the process chamber. In one embodiment, purges are performed before and after introduction of reducing agent.

Purging the chamber may involve flowing a purge gas or a sweep gas, which may be a carrier gas used in other operations or may be a different gas. In some embodiments, purging may involve evacuating the chamber. Examples of purge gases include argon (Ar), nitrogen (N₂), hydrogen (H₂), helium (He), oxygen (O₂), krypton (Kr), xenon (Xe), neon (Ne), and combinations thereof. In various embodiments, the purge gas is an inert gas. The purge gas may include one or more gases. In some embodiments, purging may include one or more evacuation subphases for evacuating the process chamber. Alternatively, it will be appreciated that purges may be omitted in some embodiments. A purge may have any suitable duration, such as between about 0 seconds and about 60 seconds, for example about 0.01 seconds.

In some embodiments, increasing a flow rate of one or more purge gases may decrease the duration of a purge. For example, a purge gas flow rate may be adjusted according to various reactant thermodynamic characteristics and/or geometric characteristics of the process chamber and/or process chamber plumbing for modifying the duration of the purge. In one non-limiting example, the duration of a purge phase may be adjusted by modulating purge gas flow rate. This may reduce deposition cycle time, which may improve substrate throughput.

The purge gas can be flowed to a chamber housing the substrate at a flow rate between about 1000 sccm and about 40000 sccm (e.g., about 100 to 2000 sccm). The purge gas can be flowed for any useful period (e.g., about 0.1 to 10 seconds) and any useful pressure (e.g., about 0.5 to 25 Torr).

FIG. 2C is a representation of another embodiment of the method; a flash enhanced pulsed chemical vapor deposition in which light irradiates a substrate during precursor delivery. The method is similar to that described in FIG. 2A above in terms of the applicable precursors, light sources, reducing agents and process conditions. However, in this embodiment, the reducing agent is continuously flowed through the chamber. This means that for a very brief time interval, on the order of 1 to 30 seconds, the precursor, the light and the reducing agent are all delivered at the same time.

In certain embodiments, flash enhanced atomic layer deposition or flash enhanced pulsed chemical vapor deposition may be utilized in the early stages of gapfill during initial nucleation of Mo. In other embodiments, flash enhanced no pulse atomic layer deposition may be utilized for bulk fill or overburden to improve throughput.

FIG. 3A illustrates an embodiment of the disclosed method in which flashes of light irradiate the substrate during purge steps, which may assist with by-product removal. Such a method may be described as an in situ rapid anneal. This embodiment of the method is similar to that described in FIG. 2B above in terms of the applicable precursors, light sources, reducing agents and process conditions. However, in this embodiment, the light irradiates the substrate during purge steps, instead of during introduction of precursor. The irradiation occurs during the purges and may be for a shorter duration or for the same duration as the purge.

In some embodiments, light may irradiate the substance during purge steps and during precursor delivery.

FIG. 3B illustrates an embodiment of the disclosed method in which the flashes of light irradiate the substrate in a pre-treatment step, prior to introduction of a metal precursor. Pre-treatment may be utilized to remove contaminants, or enable formation of a liner layer prior to metallization. Such a pre-treatment may be combined with any of the methods illustrated by FIGS. 2A-2C or FIG. 3A.

FIG. 4 illustrates an embodiment of the disclosed method in which the flashes of light irradiate the substrate during purge steps (similar to the example of FIG. 3A above), and also as a post-treatment. To encourage thermal desorption of by-products an/or contaminant removal, pulses of light can be delivered for various durations and at various frequencies until a determination has been made that required specifications have been met. The post-treatment may also be performed in conjunction with any of the methods illustrated by FIGS. 2A-2C and FIGS. 3A and 3B above.

While FIGS. 2A-2C-FIG. 4 illustrate examples of the use of a flash lamp to enhance operations such as 1) a pre-treatment; 2) while nucleation occurs; 3) during deposition; 4) during purges; or as a post-treatment, it is understood that the use of a flash lamp may also be appropriate at other steps of a cycle, up to and including a continuous use of a flash lamp throughout an entire deposition process.

The foregoing description is merely illustrative in nature and is in no way intended to limit the disclosure, its application or uses. The broad teaching of the disclosure can be implemented in a variety of forms. Therefore, while this disclosure includes particular examples, the true scope of the disclosure should not be so limited since other modifications will become apparent upon a study of the drawings, the specification and the following claims. It should be understood that one or more steps within a method may be executed in a different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

### Apparatus

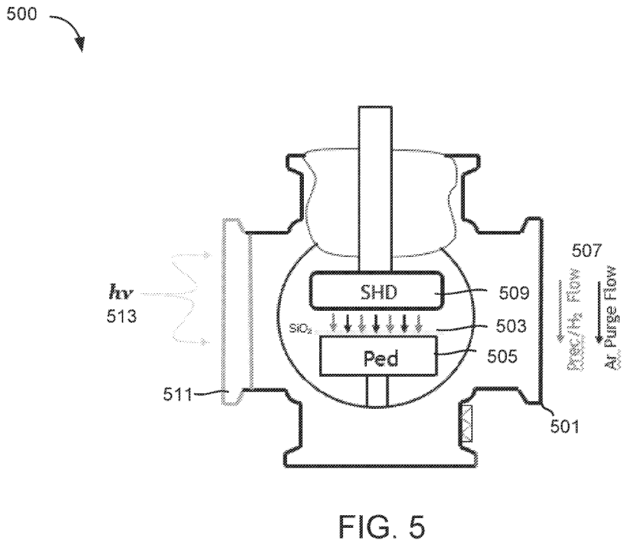

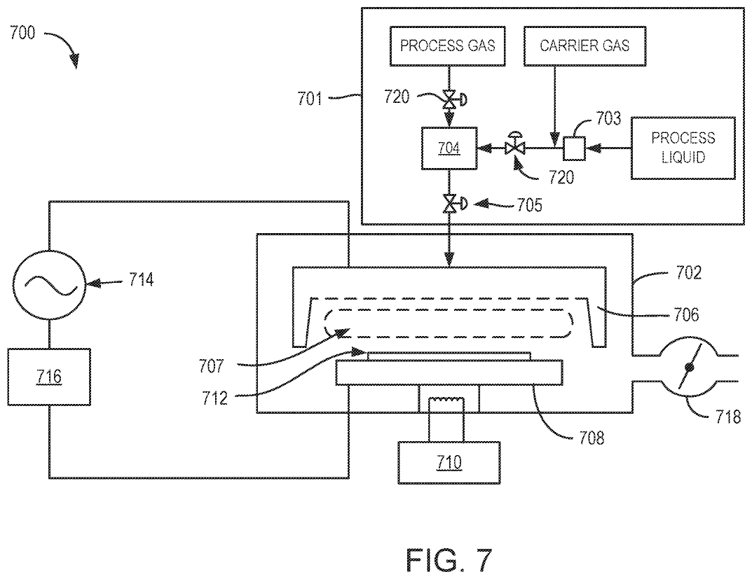

FIG. 5 is a schematic presentation of a process chamber configured to enable irradiation of a substrate from a side orientation in accordance with certain disclosed embodiments. Suitable process chambers will be described in greater detail in FIG. 7 below. Returning to FIG. 5, the schematic presentation illustrates how a light source such as a flash lamp can be integrated into a conventional process chamber. Process chamber 500 includes chamber housing 501 which includes pedestal 505. Substrate 503 rests on pedestal 505. As illustrated at 507, reagents such as metal precursors, reducing agents and purge gases can be delivered into the chamber to contact the substrate 503 from a perpendicular direction through showerhead 509. The light source may be arranged at an angle of from 0 to 180 degrees with respect to the orientation of the substrate 503. The distance of the light source from the substrate may be from about 10 cm to 1 m.

Process chamber housing 501 can be configured with a window 511 through which light from a light source 513 is permitted to enter and come into contact with substrate 503. The window 511 may be a vacuum-tight window, such as a quartz window sealed to the chamber housing 501 in certain embodiments.

Light source 513 is at least one flash lamp, such as a xenon flash lamp in certain embodiments. However, the flash lamps are not limited to xenon flash lamps and may be krypton, mercury or deuterium flash lamps. Alternatively, a combination of light sources, such as a flash lamp and a mercury vapor lamp may be utilized.

The effect of the flash lamp can be adjusted by modifying energy density (input energy or current); modifying the light pulse time (overall duration of irradiation); changing the rate of pulsing; utilizing a longer pulse; or changing the distance or angle of the flash lamp from the substrate surface. Flash lamps may be pulsed (or modulated) every pre-determined number of microseconds.

The flash lamp allows for heating and controlling substrate surface temperatures. The heating may be either of the entire top surface of the substrate 503 or directed to a selected surface region or regions of substrate 503.

Heating may be provided to predetermined depths of a substrate in a controlled and tunable manner while providing atomic reaction control. For example, in certain embodiments, heating may occur at the surface and continue for a depth of 10 to 100 nm. This may be accomplished by controlling the number, length, intensity and frequency of the light pulses being generated. In one embodiment, a series of high temperature pulses may be provided. In another embodiment, a series of low temperature pulses may be provided. In another embodiment, a combination of low temperature and high temperature pulses are provided and the durations, intensities (or power levels) and frequencies of the pulses are controlled to provide a temperature depth profile across at least a portion of a surface of a substrate.

One or more flash lamps may be utilized. When multiple flash lamps are utilized, different temperature zones may be creating by adjusting the operating conditions of each lamp accordingly. For example, a first one or more the flash lamps may be operated to provide a first series of pulses having a first set of one or more durations, one or more intensity levels (or power levels) and one or more frequencies; and a second one or more of the flash lamps may be operated to provide a second series of pulses having a second set of one or more durations, one or more intensity levels (or power levels) and one or more frequencies.

When a plurality of flash lamps is utilized, they may be rod-like lamps which may be arranged perpendicularly to each other.

In FIG. 5, the light source (flash lamp) is positioned on the side of the chamber, delivering light substantially perpendicular to and from above the substrate.

In some embodiments, process chamber 500 includes a control device (not shown) that is operatively coupled to the one or more flash lamps. In this manner, the control device can be configured to control operation of the one or more flash lamps. In some embodiments, the control device can include a processor and associated memory configured to perform a variety of computer-implemented functions.

Additionally, the control device can include a communications interface. In some implementations, the communications interface can include associated electronic circuitry that is used to send and receive data. In this manner, the control device can send one or more command signals to the one or more flash lamps via the communications interface. In some embodiments, operation of the one or more flash lamps can be control based, at least in part, on the one or more command signals.

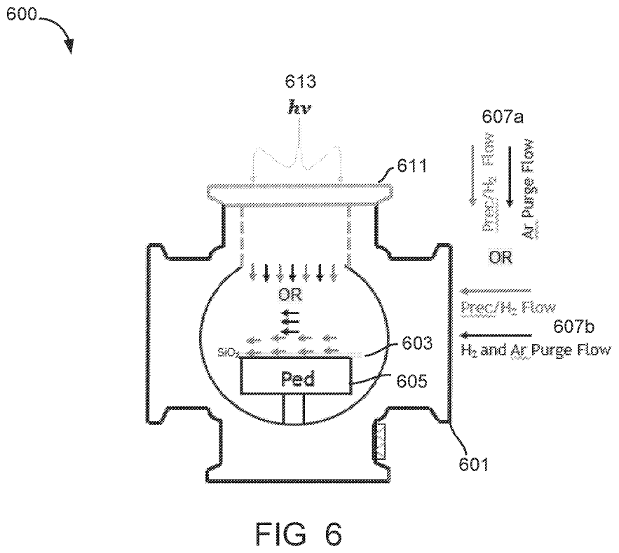

FIG. 6 is a schematic presentation of a process chamber 600 configured to enable irradiation of a substrate 603 from an orientation above the substrate 603 in accordance with certain disclosed embodiments. As previously described with reference to FIG. 5, process chamber 600 includes chamber housing 601, and pedestal 605 for supporting a substrate 603.

As illustrated at 607a, reagents such as metal precursors, reducing agents and purge gases can be delivered into the chamber to contact the substrate 603 from a substantially perpendicular direction through a showerhead (not shown). Alternatively, as illustrated at 607b, reagents may be delivered into the process chamber in a manner which is substantially parallel to the substrate.

In FIG. 6, the process chamber 600 is configured to allow irradiation from light source 613 to pass through window 611 in chamber housing 601 into the process chamber from above the substrate 603 on pedestal 605. If a showerhead (not shown) is utilized to deliver reagents into the process chamber, it must be translucent to allow light to be transmitted from the light source 613 above it. Alternatively, light source 613 may be included in a showerhead for irradiating the substrate 603.

The deposition methods described herein can be carried out in a variety of apparatuses. A suitable apparatus includes a processing chamber having one or more inlets for introduction of reactants, a substrate holder in the process chamber configured to hold the substrate in place during deposition, and, optionally, a plasma generating mechanism configured for generating a plasma in a process gas. The apparatus may include a controller having program instructions configured to cause performance of any of the method steps described herein.

For example, in some embodiments the apparatus includes a controller having program instructions that include instructions for: causing exposure of a semiconductor substrate to a silicon-containing reactant, a molybdenum-containing precursor, and a reducing agent at a temperature of between about 100° C. and about 500° C. in any of the process sequences described herein to deposit molybdenum metal and/or molybdenum silicide. The controller may include program instructions for causing any of the methods described herein.

An example of a deposition apparatus suitable for depositing molybdenum-containing films using provided methods is shown in FIG. 7. The figure schematically shows an embodiment of a process station 700 that may be used to deposit material using atomic layer deposition (ALD) and/or chemical vapor deposition (CVD), either of which may be plasma enhanced. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers.

Process station 700 fluidly communicates with reactant delivery system 701 for delivering process gases to a distribution showerhead 706. Reactant delivery system 701 includes a mixing vessel 704 for blending and/or conditioning process gases for delivery to showerhead 706. One or more mixing vessel inlet valves 720 may control introduction of process gases to mixing vessel 704. Similarly, a showerhead inlet valve 705 may control introduction of process gasses to the showerhead 706.

Some molybdenum-containing precursors may be stored in solid or liquid form prior to vaporization and subsequent delivery to the process station. For example, the embodiment of FIG. 7 includes a vaporization point 703 for vaporizing solid reactant to be supplied to mixing vessel 704. In some embodiments, vaporization point 703 may be a heated vaporizer. In some embodiments a flow of an inert gas is passed over the heated solid molybdenum precursor, or bubbled through the heated liquid molybdenum precursor, under sub-atmospheric pressure, and carries the precursor vapor to the process chamber. The precursor vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 200° C. at mixing vessel 704.

Showerhead 706 distributes process gases toward substrate 712. In the embodiment shown in FIG. 7, substrate 712 is located beneath showerhead 706, and is shown resting on a pedestal 708. It will be appreciated that showerhead 706 may have any suitable shape and may have any suitable number and arrangement of ports for distributing processes gases to substrate 712. While not explicitly shown, in some embodiments the showerhead 706 is a dual plenum showerhead that includes at least two types of conduits, where the first type of conduit is dedicated to delivery of molybdenum-containing precursor vapor, and the second type of conduit is dedicated to delivery of the second (or other) reactant. In these embodiments the molybdenum-containing precursor and the reactant are not allowed to mix in the conduits prior to entry to the process chamber, and do not share the conduits if delivered to the chamber consecutively.

In some embodiments, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some embodiments, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering a plasma. In other embodiments apparatuses without a plasma generator are used for depositing molybdenum-containing films using provided methods. In some embodiments, the plasma energy may be controlled by controlling one or more of a process station pressure, a gas concentration, a radio frequency (RF) source power, an RF source frequency, and a plasma power pulse timing. For example, RF power supply 714 and matching network 716 may be operated at any suitable power to form a plasma having a desired composition of radical species. Likewise, RF power supply 714 may provide RF power of any suitable frequency. In some embodiments, RF power supply 714 may be configured to control high- and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 708 may be temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to process station 700.

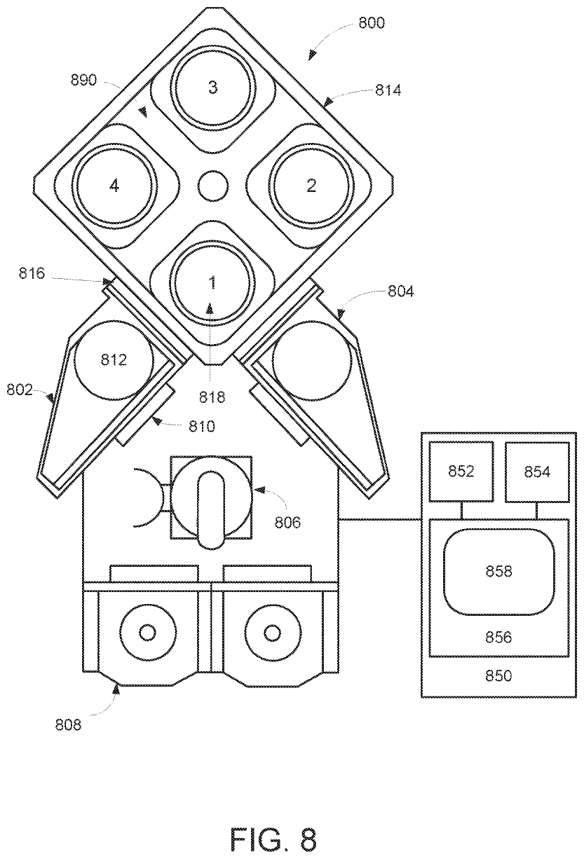

FIG. 8 shows a schematic view of an embodiment of a multi-station processing tool 800 with an inbound load lock 802 and an outbound load lock 804, either or both of which may comprise a remote plasma source. Such tool may be used for processing the substrates using the methods provided herein. A robot 806, at atmospheric pressure, is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 comprises a remote plasma source, the wafer may be exposed to a remote plasma treatment in the load lock prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc.

In some embodiments, system controller 850 controls all of the activities of process tool 800. System controller 850 executes system control software 858 stored in mass storage device 854, loaded into memory device 856, and executed on processor 852. System control software 858 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 800. System control software 858 may be configured in any suitable way. For example, various process tool component subroutines or control objects may be written to control operation of the process tool components necessary to carry out various process tool processes in accordance with the disclosed methods. System control software 858 may be coded in any suitable computer readable programming language.

In some embodiments, system control software 858 may include input/output control (IOC) sequencing instructions for controlling the various parameters described above. For example, each phase of an ALD process may include one or more instructions for execution by system controller 850. The instructions for setting process conditions for an ALD process phase may be included in a corresponding ALD recipe phase. In some embodiments, the ALD recipe phases may be sequentially arranged, so that all instructions for an ALD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Two or more of the stations may perform the same functions. Similarly, two or more stations may perform different functions. Each station can be designed/configured to perform a particular function/method as desired.

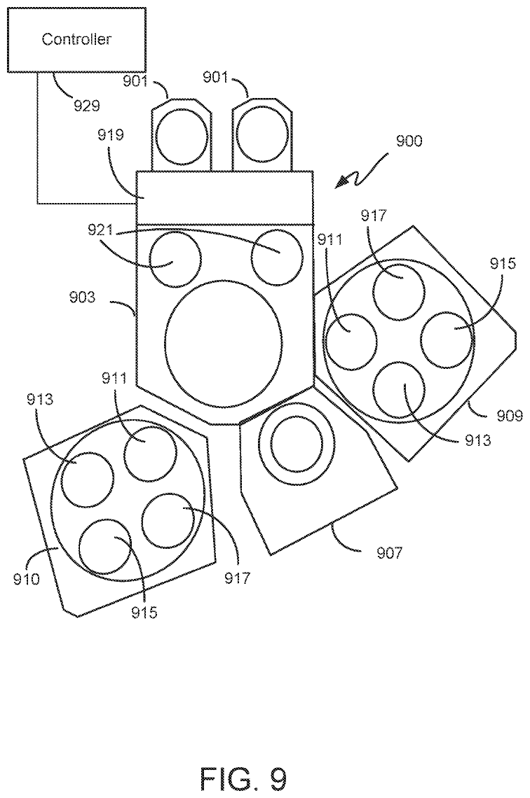

FIG. 9 is a block diagram of a processing system suitable for conducting thin film deposition processes in accordance with certain embodiments. The system 900 includes a transfer module 903. The transfer module 903 provides a clean, pressurized environment to minimize risk of contamination of substrates being processed as they are moved between various reactor modules. Mounted on the transfer module 903 are two multi-station reactors 909 and 910, each capable of performing atomic layer deposition (ALD) and/or chemical vapor deposition (CVD) according to certain embodiments. Reactors 909 and 910 may include multiple stations 911, 913, 915, and 917 that may sequentially or non-sequentially perform operations in accordance with disclosed embodiments. The stations may include a heated pedestal or substrate support, one or more gas inlets or showerhead or dispersion plate.

Also mounted on the transfer module 903 may be one or more single or multi-station modules 907 capable of performing plasma or chemical (non-plasma) pre-cleans, or any other processes described in relation to the disclosed methods. The module 907 may in some cases be used for various treatments to, for example, prepare a substrate for a deposition process. The module 907 may also be designed/configured to perform various other processes such as etching or polishing. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically, there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the silicon-containing reagent flow, reducing agent flow, and metal-containing precursor flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface. Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### Definitions

For the purposes of this disclosure, “metal” used in this context should be understood to mean conductor with a maximum resistivity of 500 micro Ohm cm, including metals and conductive metal salts, in particular conductive metal nitrides, e.g., TiN.

“Molybdenum metal” or “metallic molybdenum” as used herein, refers to material that consists essentially of molybdenum (Mo). Other elements (e.g., C, N, or O) can be present in molybdenum metal in small quantities (e.g., with a total content of less than about 15 atomic %, or less than about 10%, where hydrogen is not included in the calculation). “High purity molybdenum metal” as used herein refers to molybdenum metal that includes less than about 5% of other elements, such as less than about 1% of other elements, where hydrogen is not included in the calculation.

Molybdenum nitride (MoNₓ), molybdenum carbide (MoCₓ), molybdenum boride (MoBₓ), molybdenum silicide (MoSiₓ), molybdenum boride carbide (MoBₓC_{y}), and molybdenum carbonitride (MoCₓN_{y}), refer to materials that consist essentially of molybdenum and nitrogen (MoNₓ), molybdenum and carbon (MoCₓ), molybdenum and boron (MoBₓ), molybdenum and silicon (MoSiₓ), molybdenum, boron and carbon (MoBₓC_{y}), and molybdenum, carbon and nitrogen (MoCₓN_{y}), where x and y indicate that the stoichiometry of these compounds may vary. Other elements may be present in these compounds in small quantities, e.g., in an amount of less than about 10% atomic, where hydrogen is excluded from the calculation.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

By “aliphatic” is meant a hydrocarbon moiety having at least one carbon atom to 50 carbon atoms (C₁₋₅₀), such as one to 25 carbon atoms (C₁₋₂₅), or one to ten carbon atoms (C₁₋₁₀), and which includes saturated groups such as alkanes (or alkyl) and unsaturated groups such as alkenes (or alkenyl), alkynes (or alkynyl), and also includes cyclic versions thereof, and further including straight- and branched-chain arrangements, and all stereo and position isomers as well. Such a hydrocarbon can be unsubstituted or substituted with one or more groups, such as halogens or groups described herein for an alkyl group.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include C₂₋₈ alkenyl, C₂₋₆ alkenyl, C₂₋₅ alkenyl, C₂₋₄ alkenyl, or C₂₋₃ alkenyl. Exemplary, non-limiting alkenyl groups include vinyl or ethenyl (—CH═CH₂), 1-propenyl (—CH═CHCH₃), allyl or 2-propenyl (—CH₂—CH═CH₂), 1-butenyl (—CH═CHCH₂CH₃), 2-butenyl (—CH₂CH═CHCH₃), 3-butenyl (e.g. —CH₂CH₂CH═CH₂), 2-butenylidene (e.g., ═CH—CH═CHCH₃), and the like.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr or nPr), isopropyl (i-Pr or iPr), cyclopropyl, n-butyl (n-Bu or nBu), isobutyl (i-Bu or iBu), s-butyl (s-Bu or sBu), t-butyl (t-Bu or tBu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 3-, 4-, 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)-Het, wherein Het is heterocyclyl, as described herein); (14) hydroxyl (e.g., —OH); (15) N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group. (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-C_{y}, wherein Lk is a bivalent form of optionally substituted alkyl group and C_{y} is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₂, C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkylcarbonyl” is meant an alkyl group as previously defined appended to the parent molecular moiety through a carbonyl group. Exemplary, non-limiting alkylcarbonyl groups include methylcarbonyl, ethylcarbonyl, and isopropylcarbonyl among others.

The term “alkylsilyl”, as used herein, refers to SiR₃ group, wherein at least one R is an alkyl, and each R is independently selected from H and an alkyl. Alkylsilyls include mono, bis, and tris alkylsilyls. Examples of alkylsilyls include trimethylsilyl, dimethylsilyl, methylsilyl, triethylsilyl, diethylsilyl, and ethylsilyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. Non-limiting unsubstituted alkynyl groups include C₂₋₈ alkynyl, C₂₋₆ alkynyl, C₂₋₅ alkynyl, C₂₋₄ alkynyl, or C₂₋₃ alkynyl. Exemplary, non-limiting alkynyl groups include ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), and the like.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amido” is meant —N(R^{N1})C(O)—, where R^{N1} is H, optionally substituted alkyl, or optionally substituted aryl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aminoaryl” is meant an aryl group, as defined herein, substituted by an amino group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “azido” is meant —N₃.

By “branched alkenyl” is meant an isomer of a straight chain alkenyl compound; one having alkyl groups bonded to the main carbon chain.

By “cyano” is meant —CN.

By “carbonyl” is meant a —C(O)— group, which can also be represented as >C═O.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “deposition” or “vapor deposition” is meant a process in which a metal layer is formed on one or more surfaces of a substrate from vaporized precursor composition(s) including one or more metal containing compounds. The metal-containing compounds are vaporized and directed to and/or contacted with one or more surfaces of a substrate (i.e., semiconductor substrate or semiconductor assembly) placed in a deposition chamber. Typically, the substrate is heated. These metal containing compounds form a non-volatile, thin, uniform metal-containing layer on the surface(s) of the substrate. One operation of the method is one cycle, and the process can be repeated for as many cycles necessary to obtain the desired metal thickness.

By “dicarbonyl” is meant any moiety or compound including two carbonyl groups, as defined herein. Non-limiting dicarbonyl moieties include 1,2-dicarbonyl (e.g., R^{C1}—C(O)—C(O) R^{C2}, in which each of R^{C1} and R^{C2} is, independently, optionally substituted alkyl, halo, optionally substituted alkoxy, hydroxyl, or a leaving group); 1,3-dicarbonyl (e.g., R^{C1}—C(O)—C(R^{1a}R^{2a})—C(O) R^{C2}, in which each of R^{C1} and R^{C2} is, independently, optionally substituted alkyl, halo, optionally substituted alkoxy, hydroxyl, or a leaving group and in which each of R^{1a} and R^{2a} is, independently, H or an optional substituent provided for alkyl, as defined herein); and 1,4-dicarbonyl (e.g., R^{C1}—C(O)—C(R^{1a}R^{2a})—C(R^{3a}R^{4a})—C(O) R^{C2}, in which each of R^{C1} and R^{C2} is, independently, optionally substituted alkyl, halo, optionally substituted alkoxy, hydroxyl, or a leaving group and in which each of R^{1a}, R^{2a}, R^{3a}, and R^{4a} is, independently, H or an optional substituent provided for alkyl, as defined herein).

The term “fluoroalkyl”, as used herein, refers alkyl groups containing one or more fluorine substituents. In some implementations fluoroalkyls contain exclusively fluorine substituents, such as in CF₃, C₂F₅, C₅F₇. Fluoroalkyls may be linear, branched and cyclic.

By “halo” is meant F, Cl, Br, or I.

By “halo containing substituent” is meant a group that contains a halo, such as a haloaliphatic or haloalkyl group.

By “haloaliphatic” is meant an aliphatic group, as defined herein, substituted with one or more halo.

By “haloalkenyl” is meant an alkenyl group, as defined herein, substituted with one or more halo.

By “haloalkynyl” is meant an alkynyl group, as defined herein, substituted with one or more halo.

By “haloalkyl” is meant an alkyl group, as defined herein, substituted with one or more halogen. Non-limiting unsubstituted haloalkyl groups include C₁₋₂ haloalkyl, C₁₋₃ haloalkyl, C₁₋₄ haloalkyl, C₁₋₅ haloalkyl, C₁₋₆ haloalkyl, C₂₋₃ haloalkyl, C₂₋₄ haloalkyl, C₂₋₅ haloalkyl, C₂₋₆ haloalkyl, or C₃₋₆ haloalkyl. Other non-limiting haloalkyl groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; —CH₂CX_{y}H_{3-y}, wherein y is 1, 2, or 3, and wherein each X is, independently, halo (F, Cl, Br, or I); —CX_{z1}H_{2-z1}CX_{z2}H_{2-z2}CX_{y}H_{3-y}, wherein each of z1 and z2 is, independently, 0, 1, or 2, wherein y is 0, 1, 2, or 3, and wherein each X is, independently, halo (F, Cl, Br, or I), in which at least one of z1, z2, or y is not 0; and —CX_{z}H_{1-z}[CX_{y1}H_{3-y1}][CX_{y2}H_{3-y2}], wherein z is 0 or 1, wherein each of y1 and y2 is, independently, 0, 1, 2, or 3, and wherein each X is, independently, halo (F, Cl, Br, or I), in which at least one of z, y1, or y2 is not 0.

By “haloalkylene” is meant an alkylene group, as defined herein, substituted with one or more halo.

By “heterocyclyl” is meant a 3-, 4-, 5-, 6- or 7-membered ring, unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl, benzylsultimyl, bipyrazinyl, bipyridinyl, carbazolyl (e.g., 4H-carbazolyl), carbolinyl (e.g., β-carbolinyl), chromanonyl, chromanyl, cytdinyl, chromenyl, cinnolinyl, coumarinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “imino” is meant —NR—, in which R can be H or optionally substituted alkyl.

By “isocyanato” is meant —NCO.

By “isocyano” is meant —N^{⊕}≡C^{\textcircled{-}}—, and includes nitriles of the formula RN≡C—, wherein R is an aliphatic, aryl or heteroaryl group.

By “isothiocyanato” is meant —N═C═S.

By “low valent” is meant the lower oxidation states when a metal has multiple oxidation states.

By “oxo” is meant an ═O group.

By “oxy” is meant —O—.

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

Use of the above terms is meant to encompass substituted and unsubstituted moieties. Substitution may be by one or more groups such as alcohols, ethers, esters, amides, sulfones, sulfides, hydroxyl, nitro, cyano, carboxy, amines, heteroatoms, lower alkyl, lower alkoxy, lower alkoxycarbonyl, alkoxyalkoxy, acyloxy, halogens, trifluoromethoxy, trifluoromethyl, alkyl, aralkyl, alkenyl, alkynyl, aryl, cyano, carboxy, carboalkoxy, carboxyalkyl, cycloalkyl, cycloalkylalkyl, heterocyclyl, alkylheterocyclyl, heterocyclylalkyl, oxo, arylsulfonyl and aralkyaminocarbonyl, or any of the substituents of the preceding paragraphs or any of those substituents either directly attached or by suitable linkers. The linkers are typically short chains of 1-3 atoms containing any combination of —C—, —C(O)—, —NH—, —S—, —S(O)—, —O—, —C(O)— or —S(O)O—. Rings may be substituted multiple times.

The term “lower” modifying “alkyl”, “alkenyl”, “alkynyl”, “alkoxy” or “alkoxycarbonyl” refers to a C₁-C₆ unit for a particular functionality. For example, “lower alkyl” means C₁-C₆ alkyl.

By “substituted” is meant having one or more substituent moieties whose presence does not interfere with the desired function or reactivity. Examples of substituents alkyl, alkenyl, alkynyl, cycloalkyl (non-aromatic ring), Si(alkyl)₃, Si(alkoxy)₃, alkoxy, amino, alkylamino, alkenylamino, amide, amidine, guanidine, hydroxyl, thioether, alkylcarbonyl, alkylcaronyloxy, alkoxycarbonyloxy, carbonate, alkoxycarbonyl, aminocarbonyl, alkylthiocarbonyl, phosphate, phosphate ester, phosphonato, cyano, halo, acylamino, imino, sulfhydryl, alkylthio, thiocarboxylate, dithiocarboxylate, sulfate, sulfato, sulfonate, sulfamoyl, sulfonamide, nitro, nitrile, azido, heterocyclyl, ether, ester, silicon-containing moieties, thioester or a combination thereof. The substituents may themselves be substituted. For instance, an amino substituent may itself be mono or independently disubstituted by further substituents defined above, such as alkyl, alkenyl, alkynyl, and cycloalkyl (non-aromatic ring).

By “thiocyanato” is meant —SCN.

By “thioether” is meant to include to include both unidentate and multidentate (e.g. bidentate ot tridentate) thioethers, as well as ligands that contain both thioether and thiolate (or other) moieties.

By “unsubstituted” is meant any open valence of an atom being occupied by hydrogen. Also, if an occupant of an open valence position on an atom is not specified, then it is hydrogen.

As used herein, the term “about” is understood to account for minor increases and/or decreases beyond a recited value, which changes do not significantly impact the desired function of the parameter beyond the recited value(s). In some cases, “about” encompasses +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

As used herein, the phrase “at least one of A, B, and C” should be construed to mean a logical (A or B or C), using a non-exclusive logical “or”, and should not be construed to mean “at least one of A, at least one of B and at least one of C”.

The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like.

By “unsaturated” is meant a moiety that contains double or triple carbon-carbon bonds.

By “unsaturated substituent” is meant a double or triple bond containing aliphatic chain, cyclic, aryl or heteroaryl group.

The term “independently selected”, when referring to R substituent selection in a molecule containing multiple R groups, means that the selection of R substituents at different atoms of a molecule is independent and that the selection of R substituents at one atom having multiple R substituents is also independent.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for deposition of a metal-containing film comprising:
providing a semiconductor substrate in a processing chamber, the semiconductor substrate having a top surface and a bulk, the top surface positioned above the bulk;
introducing a metal precursor into the processing chamber;
irradiating the top surface with pulses of light from a light source;
introducing a reducing agent into the processing chamber; and
depositing a metal-containing film on the semiconductor substrate, wherein the processing chamber is maintained at a temperature of about 450° C. or less.

2. The method of claim 1, wherein the light source emits the pulses of the light of a wavelength of from about 400 to about 1100 nanometers for a duration of 0.2 microseconds to 10 milliseconds.

3. The method of claim 2, wherein irradiating the semiconductor substrate with the pulses of the light induces a temperature of the top surface higher than a temperature of the bulk.

4. The method of claim 3, wherein the temperature of the top surface is from about 500° C. to about 800° C., and the temperature of the bulk is less than 450° C.

5. The method of claim 1, wherein the metal-containing film comprises molybdenum, tungsten or ruthenium and the semiconductor substrate comprises silicon dioxide.

6. The method of claim 1, wherein the metal precursor comprises a molybdenum precursor.

7. The method of claim 6, wherein the molybdenum precursor comprises a structure of Formula (I), Formula (II) or Formula (III): 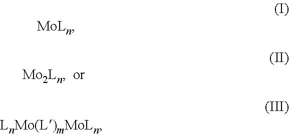
wherein:
each L is independently a monodentate ligand, ambidentate ligand, bidentate ligand or tridentate ligand,
L′ is a linking moiety,
n is 2, 3, 4, 5 or 6; and
m is 1, 2 or 3.

8. The method of claim 6, wherein the molybdenum precursor comprises a molybdenum halide or a molybdenum oxyhalide.

9. The method of claim 6, wherein the molybdenum precursor comprises Mo(CO)₆ or C₁₆H₂₀Mo.

10. The method of claim 6, wherein the molybdenum precursor comprises a low valent molybdenum precursor, wherein the low valent molybdenum precursor has an oxidation state of zero, one, two, or three.

11. The method of claim 1, wherein the light source comprises a xenon flash lamp.

12. The method of claim 1, wherein deposition occurs without increasing thermal stress on the semiconductor substrate.

13. The method of claim 1, wherein the semiconductor substrate further comprises a nucleation layer, the nucleation layer positioned above the bulk and below the top surface.

14. The method of claim 13, wherein irradiating the semiconductor substrate with the pulses of the light induces a temperature of the top surface and the nucleation layer higher than a temperature of the bulk.

15. An apparatus for processing substrates, the apparatus comprising:
one or more process chambers configured to receive a semiconductor substrate;
one or more light sources configured above the semiconductor substrate;
one or more gas inlets into the process chambers and associated flow-control hardware; and
a controller having at least one processor and a memory, wherein:
the at least one processor and the memory are communicatively connected with one another,
the at least one processor is at least operatively connected with the associated flow-control hardware, and
the memory stores computer-executable instructions for controlling the at least one processor to at least control the associated flow-control hardware to: cause emission of pulses of light from the one or more light sources to induce a transitory elevated temperature of a top surface of the semiconductor substrate and cause deposition of a metal-containing film on the semiconductor substrate.

16. The apparatus of claim 15, wherein the pulses of the light are emitted from the one or more light sources at a wavelength from about 400 to about 1100 nanometers for a duration of 0.2 microseconds to 10 milliseconds.

17. The apparatus of claim 15, wherein the one or more light sources emit light parallel to the semiconductor substrate or perpendicular to the semiconductor substrate.

18. The apparatus of claim 15, further comprising a showerhead within the one or more process chambers.

19. The apparatus of claim 18, wherein the showerhead is configured to house the one or more light sources.

20. The apparatus of claim 18, wherein the one or more light sources is configured above the showerhead, and wherein the showerhead is transparent to light.
